(19) United States
(12) Patent Application Publication
(10) Pub. No.: US 2021/0215773 A1
(43) Pub. Date: Jul. 15, 2021

(54) CONNECTION SYSTEM

(71) Applicant: SAKAI DISPLAY PRODUCTS CORPORATION, Sakai-shi, Osaka (JP)

(72) Inventor: HIROKAZU TSURUTA, Sakai-shi, Osaka (JP)

(21) Appl. No.: 17/057,925

(22) PCT Filed: May 23, 2018
(86) PCT No.: PCT/JP2018/019888

§ 371 Date: Nov. 23, 2020

(51) Int. Cl. G01R 31/66; G01R 31/28; H04B 3/04; H04B 3/46; H01B 9/00

(52) U.S. Cl. CPC G01R 31/66; G01R 31/2801; H01B 9/003; H04B 3/46; H04B 3/04

(57) ABSTRACT

A control board (1) comprises connectors (15-1, 15-2) being connectable to source driver boards (3-1, 3-2) via cables (2-1, 2-2) comprising a plurality of signal lines (22); and a control circuit (11). The control circuit (11) transmits a predetermined plurality of test data values to source driver boards (3-1, 3-2) via first signal lines of the plurality of signal lines (22). Based on one encoded data value being generated from a plurality of test data values by the source driver boards (3-1, 3-2), the control circuit (11) determines whether the plurality of test data values are correctly transmitted to the source driver boards (3-1, 3-2). The control circuit (11) outputs a signal indicating whether the plurality of test data values are correctly transmitted to the source driver boards (3-1, 3-2).

### TECHNICAL FIELD

The invention relates to a connection system comprising two electronic apparatuses being mutually connected via a cable comprising a plurality of signal lines. Moreover, the invention relates to an electronic apparatus of such a connection system. Furthermore, the invention relates to a display apparatus comprising such a connection system.

### BACKGROUND ART

An electronic device can comprise a plurality of electronic components (for example, circuit boards) being mutually connected via an attachable/detachable cable comprising a plurality of signal lines. In this case, a data signal can be transmitted between electronic components and, moreover, supply power between the electronic components via one cable.

### PRIOR ART DOCUMENT

### Patent Document

Patent Document 1: JP 2006-035597

Patent Document 2: JP 2009-061211

Patent Document 3: JP 2013-058428

### SUMMARY OF THE INVENTION

### Problem to be Solved by the Invention

A plug at the terminal end of a cable needs to be correctly inserted to a connector (or also called “a socket”) being provided in an electronic component and an electrode of the cable needs to be correctly connected to a corresponding electrode of the connector. However, the electrode of the cable can be connected to an electrode being different from the corresponding electrode of the connector due to the position at which the cable is inserted in the connector deviating from the correct position such as in a case that the cable is inserted obliquely with respect to the connector, for example. For example, when a signal line of a cable to transmit power (or, in other words, a signal line to which a power supply voltage is applied) is connected to an electrode of a connector to receive each bit of a data signal, an excessive voltage being unintended can be applied to a circuit of an electronic component, causing the electronic component to be destructed. Therefore, it is required to surely recognize whether the cable is correctly connected to the connector before supplying power between electronic components.

For example, Patent documents 1 to 3 disclose an electronic component to electrically detect whether a cable is correctly connected to a connector. Moreover, it is considered to transmit a predetermined test data value via a signal line of a cable between electronic components, for example, to electrically detect whether the cable is correctly connected to the connector. To surely detect the connection state, it is needed to transmit both bit values “1” and “0” via a signal line of interest. When a data amount of a test data value increases, a processing time to detect the connection state also increases. Therefore, an electronic apparatus that makes it possible to electrically detect whether a cable is correctly connected to a connector while suppressing an increase in required data amount and processing time is called for.

An object of the invention is to provide an electronic apparatus that makes it possible to electrically detect whether a cable is correctly connected to a connector while suppressing an increase in required data amount and processing time. Moreover, an object of the invention is to provide a connection system comprising two electronic apparatuses being mutually connected via a cable.

### Means to Solve the Problem

An electronic apparatus according to one aspect of the invention is

an electronic apparatus being a first apparatus of a connection system comprising the first apparatus and a second apparatus, the first apparatus and the second apparatus being mutually connectable via a cable comprising a plurality of signal lines, the electronic apparatus comprising:

a first connector being connectable to the second apparatus via the cable; and

a control circuit, wherein

the control circuit

transmits a predetermined plurality of test data values to the second apparatus via first signal lines of the plurality of signal lines;

based on one encoded data value being generated from the plurality of test data values by the second apparatus, determines whether the plurality of test data values are correctly transmitted to the second apparatus; and

outputs a signal indicating whether the plurality of test data values are correctly transmitted to the second apparatus.

### Effects of the Invention

The invention makes it possible to electrically detect whether a cable is correctly connected to a connector while suppressing an increase in required data amount and processing time by using one encoded data value being generated from a plurality of test data values by a second apparatus.

### BRIEF DESCRIPTION OF THE DRAWINGS

FIG. 1 shows a block diagram of an exemplary configuration of a display apparatus according to a first embodiment.

FIG. 2 shows a block diagram of an exemplary configuration of a control board and source driver boards in FIG. 1.

FIG. 3 shows an exemplary configuration of a cable in FIG. 1.

FIG. 4 shows an exemplary configuration of a cable according to a comparative example.

FIG. 5 shows a block diagram of an exemplary configuration of a control circuit in FIG. 2.

FIG. 6 shows a block diagram of an exemplary configuration of an encoding circuit in FIG. 2.

FIG. 7 shows a block diagram of an exemplary detailed configuration of the encoding circuit in FIG. 6.

FIG. 8 shows a timing chart of exemplary test data values to be transmitted to the source driver board from the control board in FIG. 1.

FIG. 9 schematically shows a flowchart of an operation of the control circuit in FIG. 1.

FIG. 10 shows a timing chart of a power supply voltage to be applied to the source driver boards from the control board in a case that cables are correctly connected to connectors of the control board and connectors of the source driver boards in FIG. 1.

FIG. 11 shows a timing chart of a power supply voltage to be applied to the source driver board from the control board in a case that the cables are not correctly connected to the connectors of the control board and the connectors of the source driver boards in FIG. 1.

FIG. 12 shows a block diagram of an exemplary configuration of the control circuit according to a variation of the first embodiment.

FIG. 13 schematically shows a flowchart of the operation of the control circuit in FIG. 12.

FIG. 14 shows a block diagram of the exemplary configuration of the control board and the source driver boards according to a second embodiment.

FIG. 15 shows an exemplary configuration of the cable in FIG. 14.

FIG. 16 shows a block diagram of the exemplary configuration of the control circuit in FIG. 14.

FIG. 17 shows a block diagram of the exemplary configuration of the encoding circuit in FIG. 14.

FIG. 18 schematically shows a flowchart of the operation of the control circuit in FIG. 14.

FIG. 19 shows a block diagram of the exemplary configuration of the source driver board according to a third embodiment.

FIG. 20 shows a block diagram of the exemplary detailed configuration of the encoding circuit in FIG. 19.

FIG. 21 shows the state of the source driver board in a case that one of source driver circuits in FIG. 19 failed.

FIG. 22 shows exemplary input and output terminals of a source driver circuit according to a variation of the third embodiment.

FIG. 23 shows a block diagram of the exemplary configuration of the control board and the source driver boards according to a fourth embodiment.

FIG. 24 shows a block diagram of the exemplary configuration of the control board and the source driver boards according to a variation of the fourth embodiment.

FIG. 25 shows an exemplary configuration of the cable in FIG. 24.

FIG. 26 shows a block diagram of the exemplary configuration of the control board and the source driver boards according to a fifth embodiment.

FIG. 27 shows an exemplary configuration of the cable in FIG. 26.

FIG. 28 shows an exemplary configuration of the cable in FIG. 26.

FIG. 29 shows a block diagram of an exemplary configuration of a parity generation circuit in FIG. 26.

FIG. 30 shows a block diagram of an exemplary configuration of the control board and the source driver boards according to a first variation of the fifth embodiment.

FIG. 31 shows a block diagram of an exemplary configuration of a parity generation circuit of the control board according to a second variation of the fifth embodiment.

### EMBODIMENT FOR CARRYING OUT THE INVENTION

Below, a display apparatus comprising a connection system according to each embodiment of the invention is explained. In each figure, the same letter indicates the same constituting element.

### First Embodiment

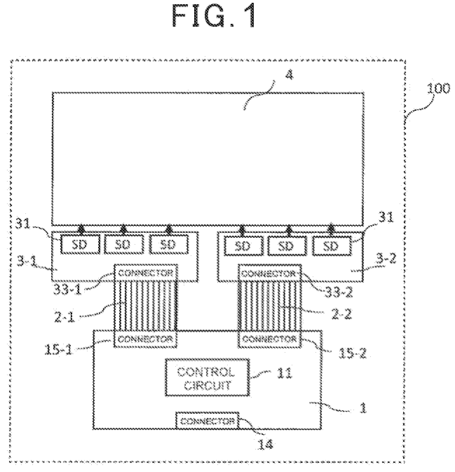

FIG. 1 is a block diagram showing an exemplary configuration of a display apparatus 100 according to a first embodiment. The display apparatus 100 comprises a control board 1; cables 2-1, 2-2; source driver boards 3-1, 3-2; and a display panel 4. The display apparatus 100 is a liquid crystal display apparatus, for example.

The control board 1 comprises a timing controller to control a gate driver circuit (not shown) and a source driver circuit (SD) 31 for the display panel 4. Each of the source driver boards 3-1, 3-2 comprises the source driver circuit (SD) 31 for the display panel 4. The control board 1 is connected to each of the source driver boards 3-1, 3-2 via the cables 2-1 and 2-2 being attachable/detachable, the cables 2-1 and 2-2 comprising a plurality of signal lines. The display panel 4 is a liquid crystal panel, for example.

In the specification, the control board 1 is also called “a first apparatus” or “a first electronic apparatus”, and, moreover, the source driver boards 3-1, 3-2 are called “a second apparatus” or “a second electronic apparatus”. Furthermore, in the specification, the control board 1 being mutually connected by the source driver boards 3-1, 3-2, and the source driver boards 3-1, 3-2 are also called “a connection system”. The same also applies in the later-described second to fifth embodiments.

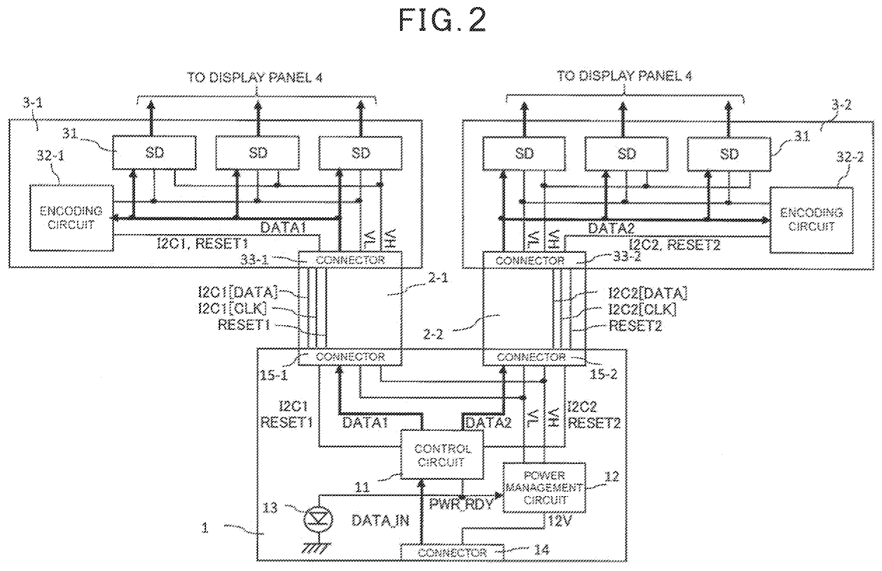

FIG. 2 is a block diagram showing an exemplary configuration of the control board 1 and the source driver boards 3-1, 3-2.

With reference to FIG. 2, the control board 1 comprises a control circuit 11; a power management circuit 12, a light emitting diode 13, and connectors 14, 15-1, and 15-2.

The connector 14 is connected to a previous-stage circuit (comprising a video processing circuit and a power supply circuit etc.) of the control board 1 via a cable (not shown). The connector 14 comprises an LVDS (low voltage differential signaling) interface, for example. One end of the cable 2-1 is attachably/detachably connected to the connector 15-1, while the connector 15-1 is connected to the source driver board 3-1 via the cable 2-1. One end of the cable 2-2 is attachably/detachably connected to the connector 15-2, while the connector 15-2 is connected to the source driver board 3-2 via the cable 2-2. The connectors 15-1, 15-2 comprise a mini-LVDS interface, for example.

The control circuit 11 is a timing controller to control a gate driver circuit (not shown) and the source driver circuit (SD) 31 for the display panel 4. The control circuit 11 receives an input data signal DATA_IN from the previous stage circuit of the control board 1 and outputs a data signal DATA1 for the source driver board 3-1 and a data signal DATA2 for the source driver board 3-2. The input data signal DATA_IN and the data signals DATA1, DATA2 show video data to be displayed on the display panel 4, for example.

Moreover, the control circuit 11 transmits, to the source driver board 3-1, a predetermined test data value to check whether the cable 2-1 is correctly connected to the connector 15-1 of the control board 1 and a connector 33-1 (described later) of the source driver board 3-1 via at least a part of signal lines to transmit the data signal DATA1. Similarly, the control circuit 11 transmits, to a source driver board (described later) 3-2, a predetermined test data value to check whether the cable 2-2 is correctly connected to the connector 15-2 of the control board 1 and a connector 33-2 (described later) of the source driver board 3-2 via at least a part of signal lines to transmit the data signal DATA2. In a case that the cable is not correctly connected to the connector and an electrode of the cable is in contact with an electrode being different from a corresponding electrode of the connector, each bit value of the test data value can reverse due to an effect of an adjacent bit value, and, moreover, can be fixed to a bit value of “0” or “1” due to an effect of the power supply voltage or the ground voltage. Furthermore, in a case that the cable is not correctly connected to the connector, the electrode of the cable is possibly not in contact with any electrode of the connector. Therefore, to surely detect the connection state, it is necessary to transmit both the bit value “1” and the bit value “0” via a signal line of interest as previously described. Therefore, the control circuit 11 transmits, to the source driver board 3-1, a plurality of test data values via the same signal line of the cable 2-1 and, moreover, transmits, to the source driver board 3-2, a plurality of test data values via the same signal line of the cable 2-2.

Furthermore, the control circuit 11 transmits/receives an I2C signal I2C1 comprising a 1-bit data value I2C1 [DATA] and a clock signal I2C1[CLK] between the control circuit 11 and an encoding circuit 32-1 (described later) of the source driver board 3-1. The control circuit 11 receives, from the encoding circuit 32-1 using the I2C signal ISC1, one encoded data value being generated from a plurality of test data values by the encoding circuit 32-1. Moreover, the control circuit 11 transmits a reset signal RESET1 to the encoding circuit 32-1. Similarly, the control circuit 11 transmits/receives an I2V signal I2C2 comprising a 1-bit data value I2C2[DATA] and a clock signal I2C2[CLK] between the control circuit 11 and an encoding circuit 32-2 (described later) of the source driver board 3-2. The control circuit 11 receives, from the encoding circuit 32-2 using the I2C signal ISC2, one encoded data value being generated from a plurality of test data values by the encoding circuit 32-2, Furthermore, the control circuit 11 transmits a reset signal RESET2 to the encoding circuit 32-2.

Moreover, the control circuit 11 determines whether the cable 2-1 is correctly connected to the connectors 15-1, 33-1 and the cable 2-2 is correctly connected to the connectors 15-2, 33-2 based on encoded data values received from the encoding circuits 32-1, 32-2, respectively. The control circuit 11 outputs a control signal PWR_RDY indicating results of the determining.

Upon supplying of a 12V power supply voltage from the previous stage circuit of the control board 1, the power management circuit 12 generates a plurality of power supply voltages for the source driver boards 3-1, 3-2, the plurality of power supply voltages being −6V, 3.3.V, 16V, and 35V, for example. In FIG. 2 and others, letters VL represent a power supply voltage of 3.3V, the power supply voltage having a minimum absolute value, while letters VH represents power supply voltages of −6V, 16V, and 35V, having greater absolute values. The power management circuit 12 always starts supplying of the 3.3.V power supply voltage to the source driver boards 3-1 and 3-2 after supplying of the 12V power supply voltage is started. On the other hand, the power management circuit 12 starts supplying of other power supply voltages of −6V, 16V, and 35V to the source driver boards 3-1, 3-2, only in a case that the cables 2-1, 2-2 are correctly connected to the connectors 15-1, 15-2, 33-1, and 33-2 based on the control signal PWR_RDY after power of the control board 1 is turned on and supplying of the 12V power supply voltage is started.

Based on the control signal PWR_RDY, the light emitting diode 13 displays whether the cables 2-1, 2-2 are correctly connected to the connectors 15-1, 15-2, 33-1, and 33-2. The light emitting diode 13 can be lit in a case that the cables 2-1, 2-2 are correctly connected to all the connectors 15-1, 15-2, 33-1, and 33-2, or, conversely, can be lit in a case that they are not correctly connected in at least one connector.

Moreover, with reference to FIG. 2, the source driver board 3-1 comprises the source driver circuit 31 in one or a plurality, the encoding circuit 32-1, and the connector 33-1. One end of the cable 2-1 is attachably/detachably connected to the connector 33-1, while the connector 33-1 is connected to the control board 1 via the cable 2-1. The connector 33-1 comprises a mini-LVDS interface, for example. Each of the source driver circuits 31 of the source driver board 3-1 receives the data signal DATA1 from the control board 1 and, moreover, upon supplying of the power supply voltages VL, VH, outputs a control signal for each pixel of the display panel 4. The encoding circuit 32-1 generates one encoded data value based on a plurality of test data values received from the control board 1.

In the same manner as the source driver board 3-1, the source driver board 3-2 comprises the source driver circuit 31 in one or a plurality, the encoding circuit 32-2, and the connector 33-2. One end of the cable 2-2 is attachably/detachably connected to the connector 33-2, while the connector 33--2 is connected to the control board 1 via the cable 2-2. The connector 33-2 comprises a mini-LVDS interface, for example. Each source driver circuit 31 of the source driver board 3-2 receives the data signal DATA2 from the control board 1 and, moreover, upon supplying of the power supply voltages VL, VH, outputs a control signal of each pixel of the display panel 4. The encoding circuit 32-2 generates one encoded data value based on a plurality of test data values received from the control board 1.

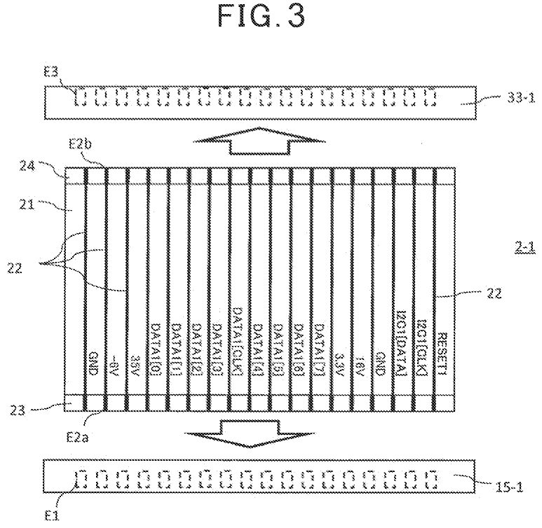

FIG. 3 shows an exemplary configuration of the cable 2-1 in FIG. 1. The cable 2-1 comprises a flexible board 21, a plurality of signal lines 22, and plugs 23, 24. The cable 2-1 is a flat cable in which the plurality of signal lines 22 are formed on the flexible board 21. The plugs 23, 24 are provided at the opposite ends of the cable 2-1. The plug 23 comprises an electrode E2a being connected to each of the signal lines 22 and is formed such that it is insertable in the connector 15-1 (socket) of the control board 1. The connector 15-1 comprises an electrode E1 to be connected to the electrode E2a of the cable 2-1. The plug 24 comprises an electrode E2b being connected to each of the signal lines 22 and is formed such that it is insertable in the connector 33-1 (socket) of the source driver board 3-1. The connector 33-1 comprises an electrode E3 to be connected to the electrode E2b of the cable 2-1.

In the example in FIG. 3, the data signal DATA1 for the source driver board 3-1 comprises an 8-bit data value DATA1[7:0] and a clock signal DATA1[CLK]. The plurality of signal lines 22 comprise 9 signal lines respectively transmitting the data value DATA1[7:0] and the clock signal DATA1[CLK] of the data signal DATA1. Moreover, the plurality of signal lines 22 comprise 3 signal lines respectively transmitting the data value I2C1[DATA] and the clock signal I2C1[CLK] of the ISC signal I2C1, and the reset signal RESET1. Moreover, the plurality of signal lines 22 comprise 4 signal lines to which power supply voltages of −6V, 3.3V, 16V, and 35V are respectively applied and 2 signal lines to which a ground voltage GND is applied. Therefore, inn the example in FIG. 3, the cable 2-1 comprises a total of 18 signal lines 22.

According to the specification, the signal line 22 to transmit the data signal DATA1 is also called “a first signal line”. Moreover, according to the specification, the signal line 22 to transmit the I2C signal is also called “a second signal line”. Furthermore, a signal line to which power supply voltages of −6V, 16V, and 35V are applied is also called “a third signal line”.

Moreover, the cable 2-2 is also similarly configured as the cable 2-1 in FIG. 3.

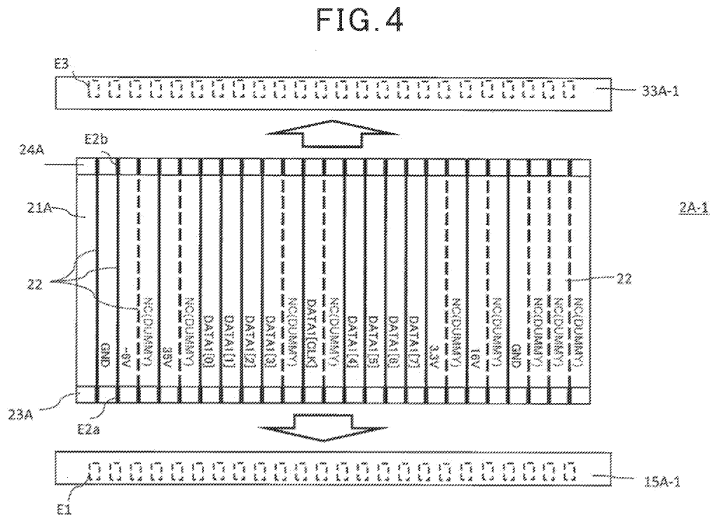

FIG. 4 shows an exemplary configuration of a cable 2A-1 in a comparative example. The cable 2A-1 comprises a flexible board 21A, a plurality of signal lines 22, and plugs 23A, 24A. The cable 2A-1. comprises the signal lines 22 in a number being different from that of the cable 2-1 in FIG. 3. Therefore, the plugs 23A, 24A have electrodes E2a, E2b in numbers being different from those of the plugs 23, 24 in FIG. 3, and the flexible board 21A and the plugs 23A, 24A have sizes being different from those of the flexible board 21 and the plugs 23, 24 in FIG. 3. Moreover, connectors 15A-1, 33A-1 also comprise electrodes E1, E3 in a number being different from that of the connectors 15-1, 33-1 in FIG. 2.

In the example in FIG. 4, the plurality of signal lines 22 comprise 9 signal lines transmitting the data value DATA1[7:0] and the clock signal DATA1[CLK] of the data signal DATA1, respectively. Moreover, the plurality of signal lines 22 comprise 4 signal lines to which power supply voltages of −6V, 3.3V, 16V, and 35V are applied respectively and 2 signal lines to which the ground voltage GND is applied. Furthermore, the plurality of signal lines 22 comprise 9 dummy (NC: not connected) signal lines to be not used to transmit power and a data signal. Therefore, in the example in FIG. 4, the cable 2A-1 comprises a total of 24 signal lines 22.

In a flat cable, it is considered to make a signal line being adjacent to a signal line to transmit power a dummy signal line not to be used to transmit power and a data signal as shown in FIG. 4 to make an occurrence of destruction of an electronic component caused by a cable not being correctly connected to a connector unlikely. In particular, it is considered to make a signal line being adjacent to each side of a signal line to which a high power supply voltage such as 16V and 35V is applied a dummy signal line. However, the size of the cable increases as a dummy signal line is provided, causing the component cost to increase and, moreover, the degree of freedom of arrangement of a cable and wiring of an electronic component to decrease. When the degree of freedom of arrangement of the cable and wiring of the electronic component decreases, an appropriate layout is possibly not obtained in a case that a wiring layout in a circuit board is determined, for example. In particular, in a case that a plurality of power supply voltages are supplied via one cable, the number of dummy signal lines increases, causing these problems to be more remarkable.

The trade-off needs to be considered between arrangement to make an occurrence of destruction of an electronic component unlikely and layout of a wiring. Excessively emphasizing prevention of destruction of an electronic component could cause wiring to be excessively congested or the size of a circuit board to increase. Moreover, making an occurrence of destruction of the electronic component unlikely could worsen electromagnetic interference or increase the time required for layout of the wiring.

Therefore, it is required to make an occurrence of destruction of an electronic component caused by a cable not being correctly connected to a connector unlikely without relying on a dummy signal line. According to the specification, a connection system is explained that makes it possible to electrically detect whether a cable is correctly connected to a connector while suppressing an increase in required data amount and processing time.

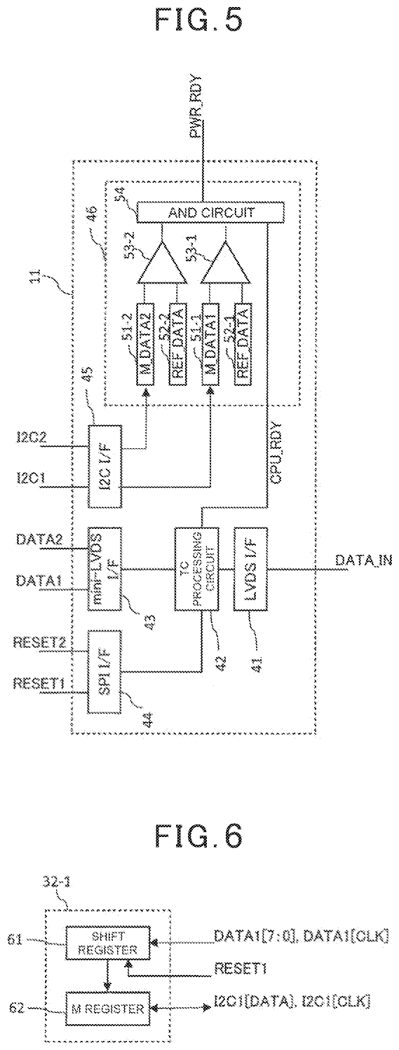

FIG. 5 is a block diagram showing an exemplary configuration of the control circuit 11 in FIG. 2. The control circuit 11 comprises an LVDS I/F (LVDS interface circuit) 41, a TC (timing control) processing circuit 42, a mini-LVDS I/F (mini-LVDS interface circuit) 43, an SPI I/F (serial peripheral interface circuit) 44, an I2C I/F (I2C interface circuit) 45, and a connection determination circuit 46.

The LVDS interface circuit receives the input data signal DATA_IN from a previous stage circuit of the control board 1. The TC processing circuit 42 processes video data comprised in the received input data signal DATA_IN, controls the operation timing of the display panel 4, and, moreover, controls the overall operation of the control circuit 11. Moreover, the TC processing circuit 42 outputs a control signal CPU_RDY indicating that the power of the control board 1 is turned on to be in the operation state. The mini-LVDS interface circuit 43 outputs the data signal DATA1 for the source driver board 3-1 and the data signal DATA2 for the source driver board 3-2. The serial peripheral interface circuit 44 outputs the reset signal RESET1 for the encoding circuit 32-1 and the reset signal RESET2 for the encoding circuit 32-2 under the control of the TC processing circuit 42. The I2C interface circuit 45 receives an encoded data value M_DATA1 from the encoding circuit 32-1 and, moreover, receives an encoded data value M_DATA2 from the encoding circuit 32-2. Based on the encoded data values M_DATA1, M_DATA2, the connection determination circuit 46 determines whether a plurality of test data values are correctly transmitted to the source driver boards 3-1, 3-2 from the control board 1 and outputs the control signal PWR_RDY indicating results of the determining.

The connection determination circuit 46 comprises registers 51-1 to 52-2, comparators 53-1, 53-2, and an AND circuit (AND logic operation circuit) 54.

The register 51-1 stores the encoded data value M_DATA1 being received from the encoding circuit 32-1. The register 51-2 stores the encoded data value M_DATA2 being received from the encoding circuit 32-2. Based on a plurality of test data values, each of the registers 52-1, 52-2 stores a precalculated reference value REF_DATA, The reference value REF_DATA represents the encoded data values M_DATA1, M_DATA2 to be generated by the encoding circuits 32-1, 32-2, respectively, in a case that the cables 2-1, 2-2 are correctly connected to the connectors 15-1, 15-2, 33-1, 33-2 and in a case that the test data value is correctly transmitted from the control board 1 to the source driver boards 3-1, 3-2.

The comparator 53-1 determines whether the encoded data value M_DATA1 matches the reference value REF_DATA and, in a case that it matches, the output signal thereof is brought to a high level, and, otherwise, the output signal is brought to a low level. Similarly, the comparator 53-2 determines whether the encoded data value M_DATA2 matches the reference value REF_DATA and, in a case that it matches, the output signal thereof is brought to a high level, and, otherwise, the output signal thereof is brought to a low level.

Based on the control signal CPU_RDY and the output signals of the comparators 53-1 and 53-2, the AND circuit 54 outputs the previously-described control signal PWR_RDY. The control signal PWR_RDY is brought to a high level in a case that the control signal CPU_RDY and all the output signals of the comparators 53-1 and 53-2 are at a high level, and is brought to a low level otherwise. In other words, in a case that the encoded data values M_DATA1, M_DATA2 match the reference value REF_DATA, the control circuit 11 determines that a plurality of test data values are correctly transmitted from the control board 1 to the source driver boards 3-1, 3-2. In this way, the control signal PWR_RDY indicates whether the plurality of test data values are correctly transmitted from the control board 1 to the source driver boards 3-1, 3-2 and, therefore, indicates whether the cables 2-1, 2-2 are correctly connected to the connectors 15-1, 15-2, 33-1, and 33-2.

The control circuit 11 can transmit identical test data values to the encoding circuit 32-1, 32-2, or can transmit mutually different test data values thereto. As shown in FIG. 5, in a case that the identical test data values are transmitted, the registers 52-1, 52-2 can store the reference values REF_DATA being identical. In a case that mutually different test data values are transmitted, each of the registers 52-1, 52-2 stores a reference value corresponding to the test data value transmitted.

FIG. 6 is a block diagram showing an exemplary configuration of the encoding circuit 32-1 in FIG. 2. The encoding circuit 32-1 comprises a shift register 61 and an M register 62. The data value DATA1[7:0] and the clock signal DATA1[CLK] of the data signal DATA1, and the reset signal RESET1 are input to the shift register 61. The data values DATA1[7:0] over at least two periods of clock signal DATA1[CLK] (in other words, at least two test data values being continuously transmitted in time) are input as a plurality of test data values to the shift register 61. The shift register 61 is associated with a predetermined generator polynomial and generates one encoded data value M_DATA1[7:0] based on a plurality of test data values received from the control board. 1.

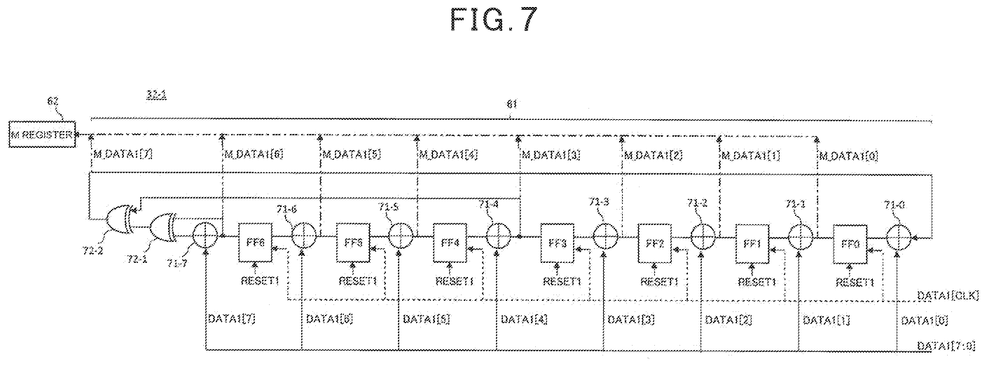

FIG. 7 is a block diagram showing an exemplary detailed configuration of the encoding circuit 32-1 in FIG. 6. As shown in FIG. 7, for example, the shift register 61 comprises adders 71-0 to 71-7, XOR circuits (XOR logic operation circuits) 72-1, 72-2, and flip flops FF0 to FF6, In the example in FIG. 7, the shift register 61 is associated with a CRC-7 generator polynomial X⁷+X³+1.

By generating the encoded data value M_DATA1 using the shift register 61, the encoded data value M_DATA1 reflects the content of the test data value of the clock signal DATA1[CLK] in the current period and the content of the test data value thereof in one period previous to the current period. Similarly, also in a case of using at least three test data values, the encoded data value M_DATA1 reflects the content of the current and the previous test data values thereof. In other words, the encoded data value M_DATA1 is generated by encoding and compressing a plurality of test data values.

Again with reference to FIG. 6, the M register 62 stores therein the encoded data value M_DATA1[7:0] being generated by the shift register 61. The encoded data value M_DATA1[7:0] being stored in the M register 62 is read by the control circuit 11 of the control board 1 using the I2C signal I2C1 comprising the data value I2C1[DATA] and the clock signal I2C1[CLK].

Moreover, the encoding circuit 32-2 is also configured in the same manner as the encoding circuit 32-1 in FIGS. 6 and 7.

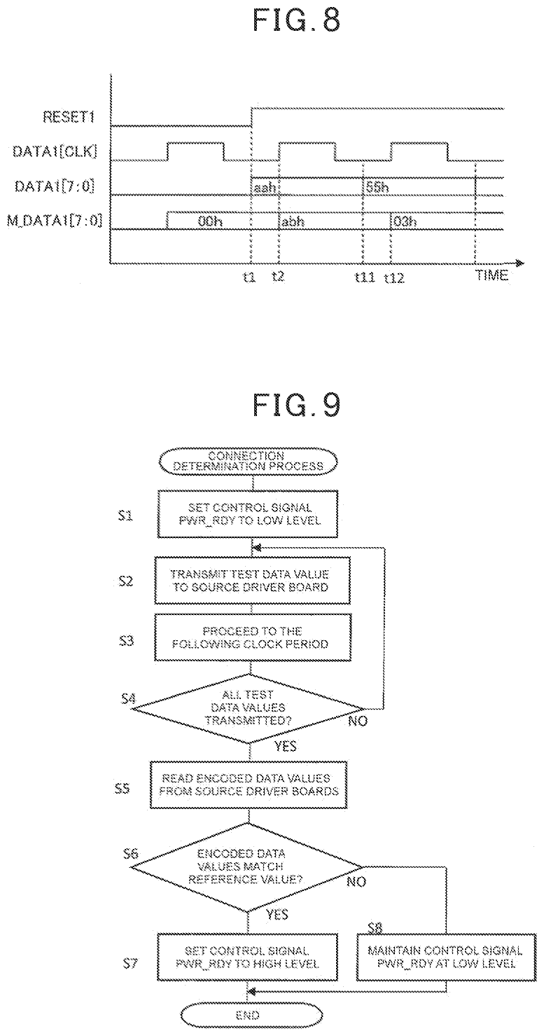

FIG. 8 shows a timing chart indicating an exemplary test data value to be transmitted to the source driver board 3-1 from the control board 1 in FIG. 1. At time t1, the shift register 61 is reset in accordance with the reset signal RESET1 and a data value DATA1[7:0]=aah is input to the shift register 61 as a first test data. value. At time t2, the shift register 61 outputs an encoded data value M_DATA1[7:0]=abh simultaneously with the rising edge of the clock signal DATA1[CLK]. At time t11, a data value DATA1[7:0]=55h is input to the shift register 61 as a second test data value. At time t12, the shift register 61 outputs an encoded data value M_DATA1[7:0]=03h simultaneously with the rising edge of the clock signal DATA1[CLK].

FIG. 9 is a flowchart schematically showing an operation of the control circuit 11 in FIG. 1.

After the power of the control board 1 is turned on, in step S1, the control circuit 11 sets the control signal PWR_RDY to a low level.

In step S2, the control circuit 11 transmits the test data value to the source driver board 3-1. In step S3, the clock signal DATA1[CLK] proceeds to the following period. Here, as explained with reference to FIG. 8, the encoding circuit 32-1 generates the encoded data value M_DATA1[7:0] based on the data value DATA1[7:0] being received as the test data value from the control board 1. In step S4, the control circuit 11 determines whether all the test data values (two data values DATA1 [7:0]=aah, 55h in the example in FIG. 8) are transmitted to the source driver board 3-1, and proceeds to step S5 in a case of YES and returns to step S2 in a case of NO.

In the same mariner as the source driver board 3-1, the control circuit 11 executes steps S2 to S4 also for the source driver board 3-2. The control circuit 11 can execute steps S2 to 54 for each of the source driver boards 3-1, 3-2 in parallel or successively.

In step S5, the control circuit 11 reads the encoded data value M_DATA1[7:0] from the encoding circuit 32-1 and reads the encoded data value M_DATA2[7:0] from the encoding circuit 32-2. In step S6, the control circuit 11 determines whether the encoded data values M_DATA1[7:0], M_DATA2[7:0] match the reference value REF_DATA, and, in a case of YES, proceeds to step S7, and, in a case of NO, proceeds to step S8. In the example of FIG. 5, determining in step S6 is carried out by the comparators 53-1, 53-2, and the AND circuit 54. In step S7, the control circuit 11 sets the control signal PWR_RDY to a high level. On the other hand, in step S8, the control circuit 11 maintains the control signal PWR_RDY at a low level.

The process in FIG. 9 can be carried out by a dedicated hardware apparatus, can be carried out software-wise using a program to be executed by a common processor, or can be carried out by a combination thereof.

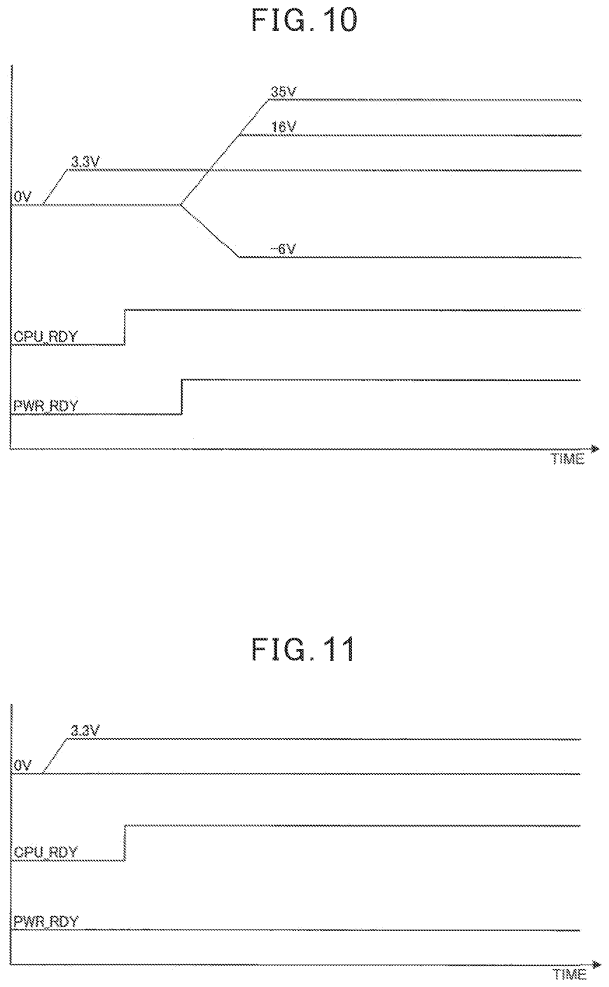

FIG. 10 is a timing chart indicating a power supply voltage applied to the source driver boards 3-1, 3-2 from the control board 1 in a case that the cables 2-1, 2-2 are correctly connected to the connectors 15-1, 15-2, 33-1, and 33-2. As previously described, the power management circuit 12 starts supplying of a power supply voltage of 3.3 V to the source drive boards 3-1, 3-2 after the power of the control board 1 is turned on and supplying of the power supply voltage of 12V is started. The power supply voltage of 3.3V is used to operate the encoding circuits 32-1, 32-2, or, in other words, to generate an encoded data value from a test data value. In a case that the cables 2-1, 2-2 are correctly connected to the connectors 15-1, 15-2, 33-1, and. 33-2, the encoded data values M_DATA:1[7:0], M_DATA.2[7:0] generated by the encoding circuits 32-1, 32-2 match the reference value REF_DATA. In a case that the control signal CPU_RDY is at a high level and the encoded data values M_DATA1[7:0], M_DATA2[7:0] match the reference value REF_DATA, the control circuit 11 sets the control signal PWR_RDY to a high level (step S7 in FIG. 9). Here, the power management circuit 12 starts supplying of other power supply voltages of −6V, 16V, and 35V to the source driver boards 3-1, 3-2.

FIG. 11 is a timing chart indicating a power supply voltage applied to the source driver boards 3-1, 3-2 from the control board 1 in a case that the cables 2-1, 2-2 are not correctly connected to the connectors 15-1, 15-2, 33-1, 33-2. In a case that the cables 2-1, 2-2 are riot correctly connected to the connectors 15-1, 15-2, 33-1, 33-2, the encoded data values M_DATA1[7:0], M_DATA2[7:0] generated by the encoding circuits 32-1, 32-2 do not match the reference value REF_DATA. In this case, the control circuit 11 maintains the control signal PWR_RDY at a low level (step S8 in FIG. 9). Therefore, the power management circuit 12 does not supply other power supply voltages of −6V, 16V, and 35V to the source driver boards 3-1, 3-2.

The process in FIG. 9 can be executed for each time the power of the display apparatus 100 is turned on, or, in other words, the power of the control board 1 is turned on.

The control board 1 and the source driver boards 3-1, 3-2 according to the first embodiment have the following advantages, for example.

According to the first embodiment, a plurality of test data values are encoded and compressed to cause encoded data values to be generated, so that the data amount and the receiving time of the encoded data value received from the encoding circuits 32-1, 32-2 by the control circuit 11 are decreased compared to a case in which they are not compressed. In this way, whether the cables 2-1, 2-2 are correctly connected to the connectors 15-1, 15-2, 33-1, 33-2 can be electrically detected while suppressing an increase in required data amount and processing time.

Furthermore, according to the first embodiment, whether the cables 2-1, 2-2 are correctly connected to the connectors 15-1, 15-2, 33-1, 33-2 are electrically detected, making it possible to make an occurrence of destruction of an electronic component caused by the cables being not correctly connected to the connectors unlikely without depending on a dummy signal line. The dummy signal line becomes unnecessary in the cables 2-1, 2-2, so that, compared to a case in which a dummy signal line exists, the sizes of the cable and the connector decrease, the cost of components decreases, and, moreover, the degree of freedom of arrangement of a cable and wiring of an electronic component improves.

Moreover, according to the first embodiment, required signal lines other than the signal line to supply the data signal and the power to the source driver circuit 31 are only three signal lines to transmit the data value and the clock signal of the I2C signal, and the reset signal, respectively. The first embodiment can be realized by adding a very small number of signal lines.

Furthermore, according to the first embodiment, in a case that the plurality of test data values are correctly transmitted to the source drive boards 3-1, 3-2 from the control board 1, supplying of power to the source driver boards 3-1, 3-2 is started, making it possible to make an occurrence of destruction of an electronic component caused by the cables being not correctly connected to the connectors unlikely. In the prior art connector, in arranging the electrodes thereof, a constraint to make the voltage difference between mutually adjacent signal lines in the cable as small as possible, or a constraint to cause a dummy signal line to be adjacent to a signal line to which a high voltage of 16V or 35V is applied is necessary. According to the first embodiment, such a constraint is unnecessary, so that electrodes of each of the connectors 15-1, 15-2, 33-1, 33-2 can be arbitrarily arranged and layout of wirings can be arbitrarily determined regardless of the voltage applied to each of the signal lines. For example, the electrodes of the connectors can be arranged such that a signal line to which a power supply voltage of 16V is applied and a signal line to which a power supply voltage of 35V is applied are adjacent to each other. Moreover, resistance to electromagnetic interference can be improved and time required for laying out the wirings can be shortened with respect to the prior art while making an occurrence of destruction of an electronic component difficult.

Furthermore, according to the first embodiment, the process in FIG. 9 can be executed each time the power of the display apparatus 100 is turned on to check the connection state of the cables 2-1, 2-2 and the connectors 15-1, 15-2, 33-1, and 33-2 even after the display apparatus 100 is shipped from a factory. Therefore, it is possible to cause an occurrence of destruction of an electronic component of the display apparatus 100 unlikely even when the connection state of a cable and a connector changes due to some cause such as vibrations (for example, vibrations during transport), or a disaster to cause the cable to be not correctly connected to the connector.

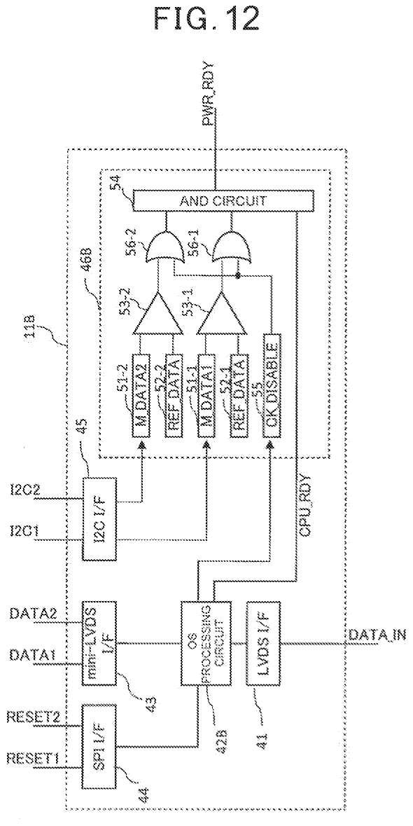

FIG. 12 is a block diagram showing an exemplary configuration of a control circuit 11B according to a variation of the first embodiment. The connection state of the cable and the connector can be executed each time the power of the apparatus is turned on, or, instead thereof, it can be executed only once when the power of the apparatus is initially turned on, for example, after the cable is connected to the connector.

In replacement of the TC processing circuit 42 and the connection determination circuit 46 of the control circuit 11 in FIG. 5, a control circuit 11B in FIG. 12 comprises a TC processing circuit 42B and a connection determination circuit 46B.

The TC processing circuit 42B outputs a bit value CK_DISABLE indicating whether a plurality of test data values are correctly transmitted to the source driver boards 3-1, 3-2 from the control board 1. The bit value CK_DISABLE turns to a high level in a case that the plurality of test data values are correctly transmitted to the source driver boards 3-1, 3-2 from the control board 1 and turns to a low level otherwise.

The connection determination circuit 46B comprises a register 55 and OR circuits (OR logic operation circuits) 56-1, 56-2 in addition to each constituting element in FIG. 5. The register 55 stores the bit value CK_DISABLE therein. The OR circuit 56-1 is brought to be at a high level in a case that at least one of the output signal of the comparator 53-1 and the bit value CK_DISABLE is at a high level and is brought to be at a low level otherwise. The OR circuit 56-2 is brought to be at a high level in a case that at least one of the output signal of the comparator 53-2 and the bit value CK_DISABLE is at a high level and is brought to be at a low level otherwise. The AND circuit 54 outputs the previously-described control signal PWR_RDY based on the output signal of the OR circuits 56-1, 56-2 in replacement of the comparators 53-1, 53-2.

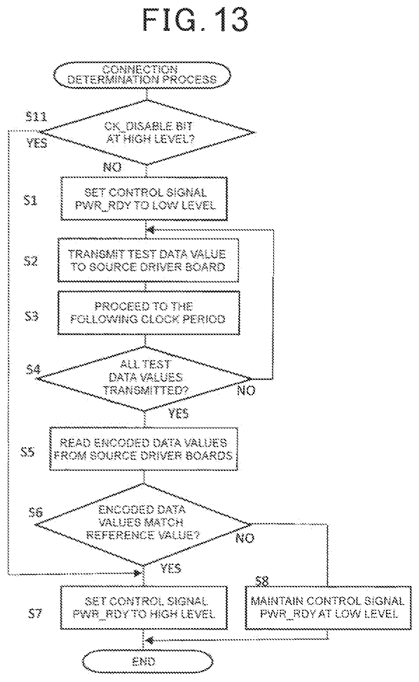

FIG. 13 schematically shows a flowchart of the operation of the control circuit 11B in FIG. 12. After the power of the control board 1 is turned on, in step S11, the control circuit 11B determines whether the bit value CK_DISABLE is at a high level, and proceeds to step S7 in a case of YES and proceeds to step S1 in a case of NO. The subsequent operation is the same as the process in FIG. 9. Therefore, the control circuit 11B executes steps S1 to S6 in a case that the power of the control board 1 is turned on and the plurality of test data values are not correctly transmitted. to the source driver boards 3-1, 3-2 from the control board 1.

According to a variation in FIGS. 12 and 13, the connection state of the cables 2-1, 2-2 and the connectors 15-1, 15-2, 33-1, and 33-2 can be checked only before shipping the display apparatus 100 from a factory, for example. The variation can be applied in a case that the form of sales of the display apparatus 100 does not assume maintenance by an engineer or a user, for example.

### Second Embodiment

While the control circuit 11 of the control board 1 determines whether the encoded data value matches the reference value according to the first embodiment, the source driver board can determine it instead.

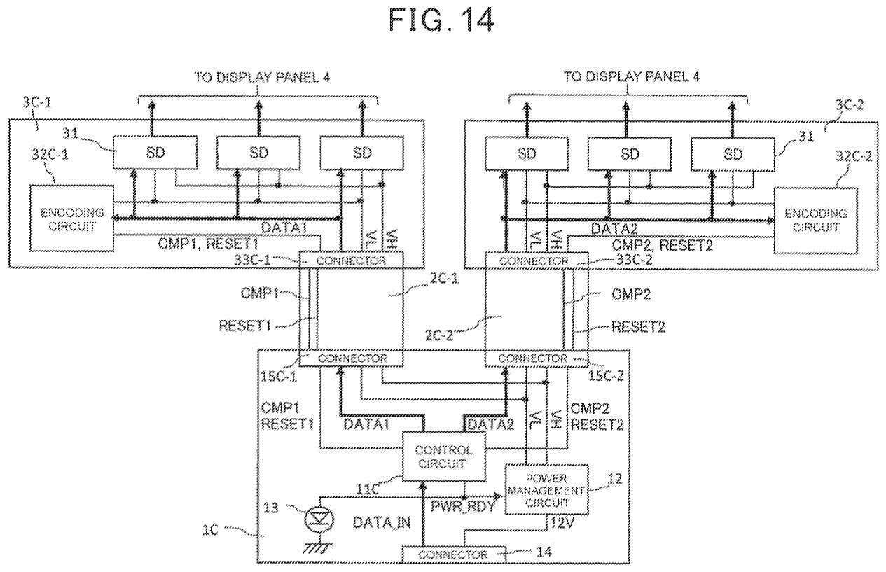

FIG. 14 shows a block diagram of the exemplary configuration of a control board 1C and source driver boards 3C-1, 3C-2 according to a second embodiment.

The control board 1C comprises a control circuit 11C and connectors 15C-1, 15C-2 in replacement of the control circuit 11 and the connectors 15-1, 15-2 in FIG. 2.

As described later, cables 2C-1, 2C-2 comprise signal lines 22 in a number being different from that of the cable 2-1 in FIG. 3, so that the connectors 15C-1 and 15C-2 comprises electrodes E1 in a number being different from that of the connectors 15-1, 15-2 in FIG. 2.

In the same manner as the control circuit 11 in FIG. 2, the control circuit 11C transmits a test data value to source driver boards 3C-1, 3C-2, respectively, via at least a part of signal lines to transmit data signals DATA1, DATA2.

Moreover, instead of transmitting/receiving the I2C signal I2C1 in FIG. 2, the control circuit 11C receives, from an encoding circuit 32C-1 (described later of the source driver board 3C-1, a one-bit bit value CMP1 indicating whether an encoded data value matches s reference value being precalculated based on a plurality of test data values. Furthermore, the control circuit 11C transmits a reset signal RESET1 to an encoding circuit 32C-1. Similarly, instead of transmitting/receiving the I2C signal 1202 in FIG. 2, the control circuit 11C receives, from an encoding circuit 32C-2 (described later) of a source driver board 3C-2, a one-bit bit value CMP2 indicating whether an encoded data value matches a reference value being precalculated based on a plurality of test data values. Moreover, the control circuit 11C transmits a reset signal RESET2 to an encoding circuit 32C-2.

Based on bit values CMP1, CMP2 received from the encoding circuits 32C-1, 32C-2, respectively, the control circuit 11C further determines whether the cable 2-1 is correctly connected to the connector 15C-1 of the control board 1C and a connector 33C-1 (described later) of the source driver board 30-1 and whether the cable 2-2 is correctly connected to the connector 15C-2 of the control board 1C and a connector 33C-2 (described later) of the source driver board. 3C-2. The control circuit 11C outputs a control signal PWR_RDY indicating results of the determining.

Furthermore, in replacement of the encoding circuit 32-1 and the connector 33-1 in FIG. 2, the source driver board 3C-1 comprises the encoding circuit 32C-1 and the connector 33C-1. In the same manner as the connector 15C-1 of the control board 1C, the connector 33C-1 comprises electrodes E3 in a number being different from that of the connector 33-1 in FIG. 2. The encoding circuit 32C-1 generates one encoded data value based on a plurality of test data values received from the control board 1C and, moreover, generates the bit value CMP1 indicating whether the encoded data value matches the reference value.

In the same manner as the source driver board 3C-1, the source driver board 3C-2 comprises the encoding circuit 32C-2 and the connector 33C-2 in replacement of the encoding circuit 32-2 and the connector 33-2 in FIG. 2. In the same manner as the connector 15C-2 of the control board 1C, the connector 33C-2 comprises electrodes E3 in a number being different from that of the connector 33-2 in FIG. 2. The encoding circuit 32C-2 generates one encoded data value based on a plurality of test data values received from the control board 1C and, moreover, generates the bit value CMP2 indicating whether the encoded data value matches the reference value.

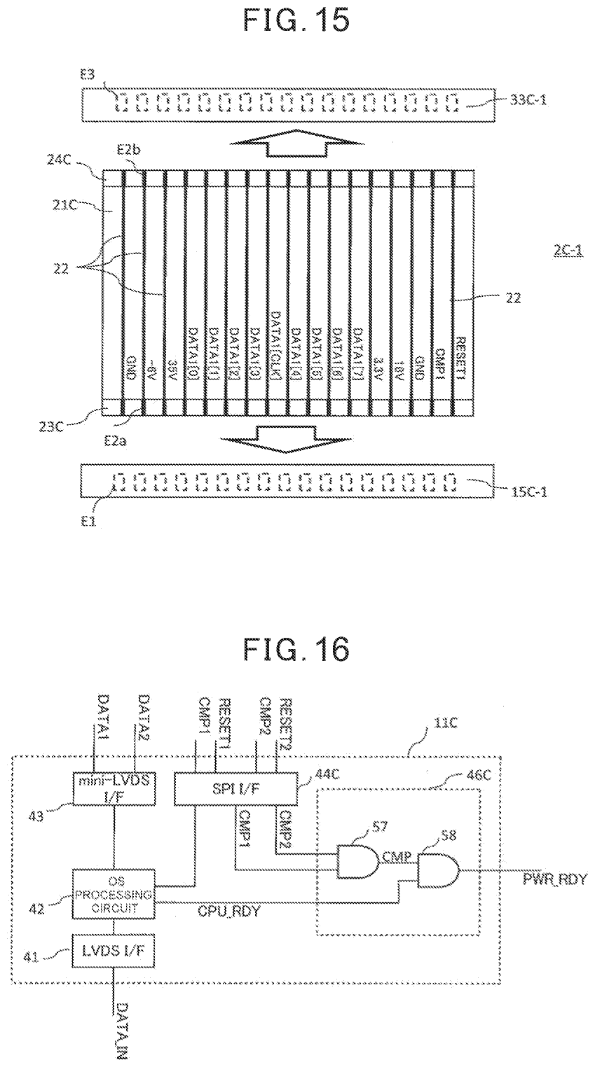

FIG. 15 shows an exemplary configuration of the cable 2C-1 in FIG. 14. The cable 2C-1 comprises a flexible board 21C, a plurality of signal lines 22, and plugs 23C, 24C. The cable 2C-1 comprises signal lines 22 in a number being different from that of the cable 2-1 in FIG. 3. Therefore, the plugs 23C, 24C comprise electrodes E2a, E2b in a number being different from that of the plugs 23, 24 in FIG. 3 and the flexible board 21C and the plugs 23C, 24C have sizes being different from those of the flexible board 21 and the plugs 23, 24.

In the example in FIG. 15, the plurality of signal lines 22 comprise one signal line to transmit the bit value CMP1 in replacement of the two signal lines to transmit the I2C signal I2C1 in FIG. 3. Therefore, in the example in FIG. 15, the cable 2C-1 comprises a total of 17 of the signal lines 22.

In the specification, the signal line 22 to transmit the bit value CMP1 is also called “a second signal line”.

Moreover, the cable 2C-2 is also configured in the same manner as the cable 20-1 in FIG. 15.

FIG. 16 shows a block diagram of the exemplary configuration of the control circuit IIC in FIG. 14. The control circuit 11C comprises a serial peripheral interface circuit 44C and a connection determination circuit 46C in replacement of the serial peripheral interface circuit 44, the I2C interface circuit 45, and the connection determination circuit 46 in FIG. 5.

Under the control of a TC processing circuit 42, the serial peripheral interface circuit 44C outputs the reset signal RESET1 for the encoding circuit 320-1 and the reset signal RESET2 for the encoding circuit 32C-2. The serial peripheral interface circuit 44C further receives the bit value CMP1 from the encoding circuit 320-1 and, moreover, receives the bit value CMP2 from the encoding circuit 32C-2. Based on the bit values CMP1, CMP2, the connection determination circuit 460 determines whether a plurality of test data values are correctly transmitted to the source driver boards 3C-1, 3C-2 from the control board 1C and outputs the control signal PWR_ RDY indicating results of the determining.

The connection determination circuit 46C comprises AND circuits 57, 58. The AND circuit 57 outputs a bit value CMP based on the bit values CMP1, CMP2. The bit value CMP is brought to be at a high level in a case that both the bit values CMP1, CMP2 are at a high level and is brought to be at a low level otherwise. The AND circuit 58 outputs the previously-described control signal PWR_RDY based on a control signal CPU-RDY and the bit value CMP. The control signal PWR-RDY is brought to be at a high level in a case that both the control signal CPU_RDY and the bit value CMP are at a high level and is brought to be at a low level otherwise. In other words, the control circuit 11C determines whether a plurality of test data values are correctly transmitted to the source driver boards 3C-1, 3C-2 from the control board 1C based on the bit values CMP1, CMP2 received from the encoding circuits 32C-1, 32C-2. The bit values CMP1, CMP2 are generated based on encoded data values, so that the control circuit 11C determines, based on the encoded data values, whether a plurality of test data values are correctly transmitted to the source driver boards 3C-1, 3C-2 from the control board 1C. In this way, the control signal PWR-RDY indicates whether the plurality of test data values are correctly transmitted to the source driver boards 3C-1, 3C-2 from the control board 1C and, therefore, whether the cables 2C-1, 2C-2 are correctly connected to the connectors 15C-1, 15C-2, 33C-1, and 33C-2.

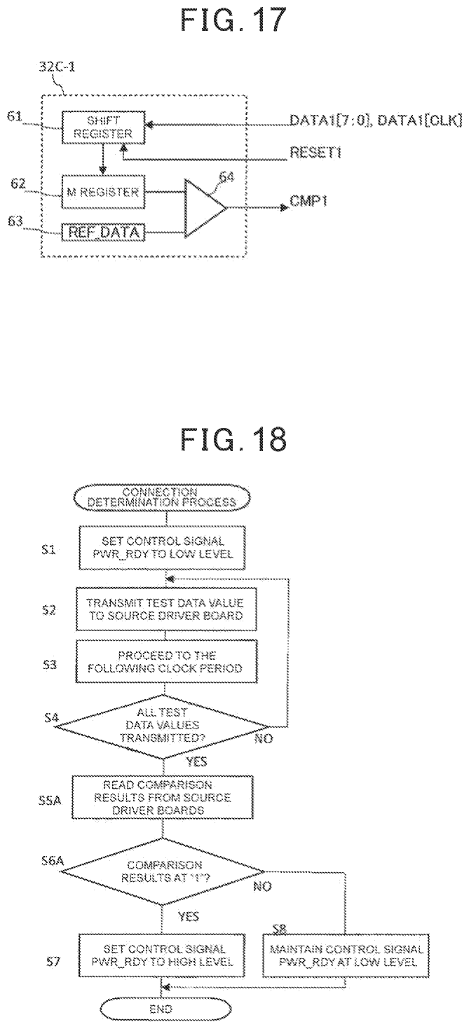

FIG. 17 shows a block diagram of the exemplary configuration of the encoding circuit 32C-1 in FIG. 14. In addition to each of the constituting elements in FIG. 6, the encoding circuit 32C-1 comprises a register 63 and a comparator 64. The register 63 stores therein a reference value REF_DATA in the same manner as the register 52-1 in FIG. 5. In the same mariner as the comparator 53-1 in FIG. 5, the comparator 64 determines whether an encoded data value M_DATA1 being generated by a shift register 61 and stored in an M register 62 matches the reference value REF_DATA and outputs the previously--described bit value CMP1 as results of the determining. In a case that the encoded data value M_DATA1 matches the reference value REF_DATA, the bit value CMP1 is brought to be at a high level, and is brought to be at a low level otherwise. The hit value CMP1 being output from the comparator 64 is received by the control circuit 11C as described previously.

Moreover, the encoding circuit 32C-2 is also configured in the same manner as the encoding circuit 32C-1 in FIG. 17.

FIG. 18 schematically shows a flowchart of the operation of the control circuit 11C in FIG, 14.

Steps S1 to S4 in FIG. 18 are similar to steps S1 to S4 in FIG. 9. After generating the encoded data values M_DATA1, M_DATA2, the encoding circuits 32C-1, 32C-2 generate the bit values CMP1, CMP2, respectively, the bit values CMP1, CMP2 indicating whether the encoded data values M_DATA1, M_DATA2 match the reference value REF_DATA.

In step S5A, the control circuit 11C receives the bit value CMP1 of comparison. results from the encoding circuit 32C-1 and receives the bit value CMP2 of comparison results from the encoding circuit 32C-2. In step S6A, the control circuit 11C determines whether both the bit values CMP1, CMP2 are at a high level, and proceeds to step S7 in a case of YES and proceeds to step S8 in a case of NO. Determining of step S6A is carried out by the AND circuits 57, 58 in the example in FIG. 16.

Steps S7 to S8 in FIG. 18 are similar to steps S7 to S8 in FIG. 9.

A power supply voltage can be applied to the source driver boards 3C-1, 3C-2 from the control board 1C in the same manner as the case explained with reference to FIGS. 10 and 11 regardless of whether the cables 2C-1, 2C-2 are correctly connected to the connectors 15C-1, 15C-2, 33C-1, 33C-2.

The control board 1C and the source driver boards 3C-1, 3C-2 according to the second embodiment have the following advantages for example, in addition to the advantages of the first embodiment.

According to the second embodiment, in replacement of the encoded data values M_DATA1, M_DATA2, the control circuit 11C receives, from the encoding circuits 32C-1, 32C-2, the bit values CMP1, CMP2, respectively, so that the amount of data to be received from the encoding circuits 32C-1, 32C-2 by the control circuit 11C and the reception time is further reduced in comparison to the first embodiment.

Moreover, according to the second embodiment, the bit values CMP1, CMP2 are 1-bit binary signals, causing an occurrence of a communication. error to be more unlikely relative to a case in. which. multibit encoded data values M_DATA1, M_DATA2 are transmitted via the cables 2-1, 2-2 as in the first embodiment.

Furthermore, the second embodiment makes the registers 51-1 to 52-2 and the comparators 53-1, 53-2 in FIG. 5 unnecessary for the control board 1C, making it possible to reduce the circuit size of the control board 1C and reduce the size and cost of components.

Moreover, the second embodiment makes a process of reading an encoded data value using an I2C signal unnecessary, making it possible to reduce the size of programs of the control circuit 11C relative to the first embodiment.

Furthermore, according to the second embodiment, signal lines required other than signal lines to supply a data signal and power to the source driver circuit 31 are merely two signal lines to transmit a bit value of comparison results, and a reset signal, respectively. The second embodiment can be realized by adding signal lines in a number being less than that in the first embodiment.

### Third Embodiment

According to the first and second embodiments, an encoded data value is generated only from a plurality of test data values. However, the encoded data value can be generated based on a signal showing the state of a different signal source (for example, an internal circuit of a source driver board), the signal being obtained from the different signal source, in addition to the plurality of test data values. In this way, the state of a different signal source in addition to the connection state of a cable and a connector can be detected.

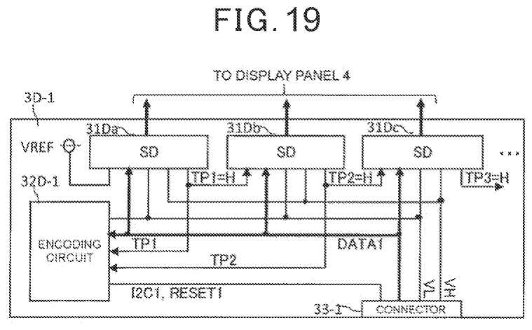

FIG. 19 shows a block diagram of the exemplary configuration of a source driver board 3D-1 according to a third

embodiment. The source driver board 3D-1 comprises a plurality of source driver circuits 31Da to 31Dc, an encoding circuit 32D-1, and a connector 33-1.

In the same manner as in the first embodiment, the connector 33-1 is connected to the control board 1 via the cable 2-1.

The source driver circuits 31Da to 31Dc receive a data signal DATA1 from the control board 1 and, moreover, upon supplying of a power supply voltage VL, VH outputs a control signal for each pixel of a display panel 4. Moreover, each of the source driver circuits 31Da to 31Dc comprises a pair of test terminals (below called “a test input terminal” and “a test output terminal”) to and from which is output/input a signal to easily test whether the circuit normally operates. A voltage corresponding to a high-level bit value is applied from a reference voltage source VREF to the test input terminal of the source driver circuit 31Da and the source driver circuit 31Da outputs a bit value TP1 from the above-mentioned test output terminal. The bit value TP1 is input to the test input terminal of the source driver circuit 31Db and the source driver circuit 31Db outputs a bit value TP2 from the above-mentioned test output terminal. The bit value TP2 is input to the test input terminal of the source driver circuit 31Dc and the source driver circuit 31Dc outputs a bit value TP3 from the above-mentioned test output terminal.

When each of the source driver circuits 31Da to 31Dc outputs a high-level bit value “H” from a test output terminal in a case that the high-level bit value “H” is input from the test output terminal, it is assumed to operate normally. Moreover, when each of the source driver circuits 31Da to 31Dc outputs a low-level bit value “L” from a test input terminal in a case that the low-level bit value “L” is input from the test input terminal, it is assumed to be in a failure. Therefore, the bit values TP1 to TP3 show whether each of the source driver circuits 31Da to 31Dc operates normally. FIG. 19 shows a case in which all the source driver circuits 31Da to 31Dc operate normally.

The encoding circuit 32D-1 generates one encoded data value based on a plurality of test data values received from the control board 1 and the bit values TP1, TP2.

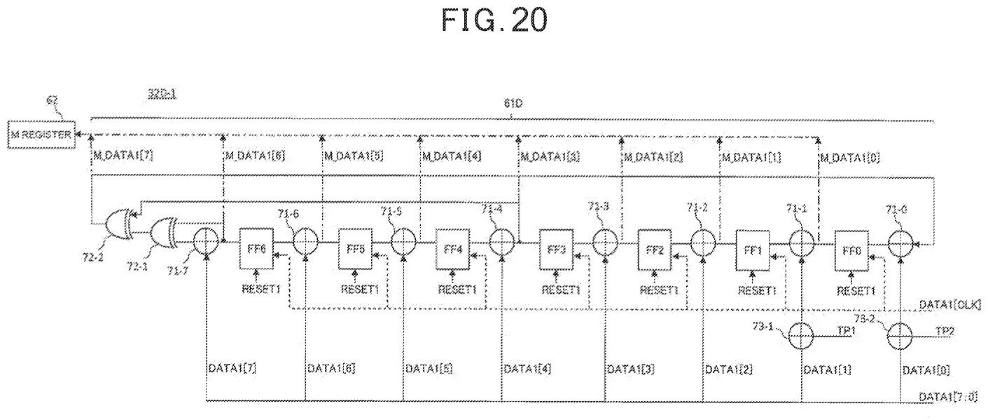

FIG. 20 shows a block diagram of an exemplary detailed configuration of the encoding circuit 32D-1 in FIG. 19. The encoding circuit 32D-1 comprises a shift register 61 and an M register 62. The shift register 61D comprises adders 73-1 and 73-2 in addition to each constituting element of the shift register 61 in FIG. 7. The adder 73-1 calculates a sum of a data value DATA1[1] and the bit value TP1 to input the calculated results to an adder 71-1. The adder 73-2 calculates a sum of a data value DATA1[0] and the bit value TP2 to input the calculated results to an adder 71-0. In this way, the shift register 61D generates an encoded data value showing the states of the source driver circuits 31Da, 31Db in addition to the connection state of the cable and the connector. The M register 62 in FIG. 20 is configured in the same manner as the M register 62 in FIGS. 6 and 7.

A control circuit 11 of the control board 1 stores, in a register 52-1 inside thereof, a reference value showing an encoded data value generated by the encoding circuit 32D-1 in a case that the cable 2-1 is correctly connected to connectors 15-1, 15-3 and a test data value is correctly transmitted from the control board 1 to the source driver board 3D-1 and both the source driver circuits 31Da, 31Db operate normally. In this way, in a case that the encoded data value match the reference value, the control circuit 11 determines that a plurality of test data values are correctly transmitted from the control board 1 to the source driver board 3D-1 and an internal circuit of the source driver board 3D-1 operates normally.

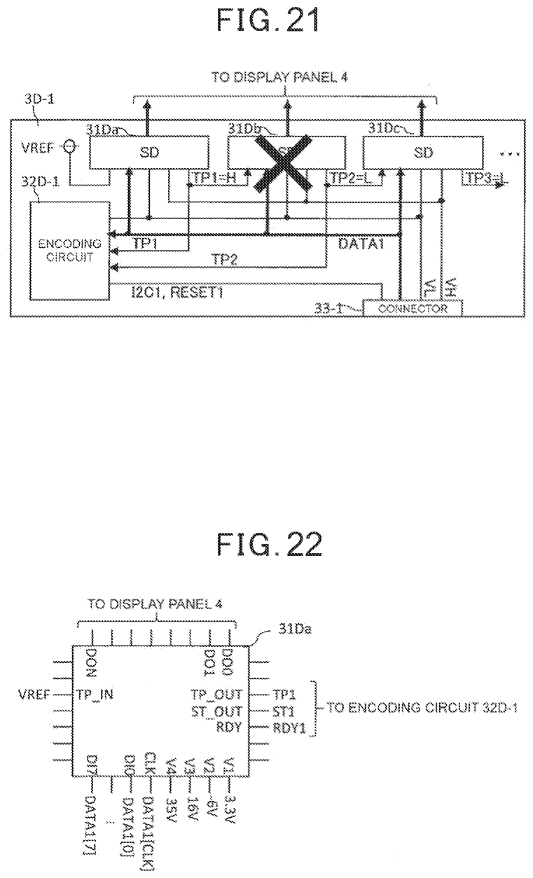

FIG. 21 shows the state of the source driver board in a case that one of the source driver circuits 31Da to 31Dc in FIG. 19 failed. FIG. 21 indicates a case in which a source driver circuit 31Db fails and the bit value TP2 is brought to be at a low level. In this case, the encoded data value does not match the reference value. Therefore, the control circuit 11 determines that the cable 2-1 is not correctly connected to the connectors 15-1, 33-1 or an internal circuit of the source driver board 3D-1 is in a failure.

The source driver board 3D-1 according to the third embodiment has the following advantages, for example, in addition to the advantages of the first and second embodiments.

According to the third embodiment, one encoded data value can be generated by the encoding circuit 32D-1 based on a plurality of test data values and the bit values TP1, TP2 to detect the state of the internal circuit of the source driver board 3D-1 in addition to the connection state of the cable and the connector. This makes it possible to prevent burning caused by a failure of the internal circuit of the source driver board D-1.

FIG. 22 shows exemplary input and output terminals of the source driver circuit 31Da according to a variation of the third embodiment. The source driver circuit 31Da in FIG. 22 comprises a test input terminal TP_IN and a test output terminal TP_OUT. The source driver circuit 31Da can input, to the encoding circuit 32D-1, a different signal showing the state of the source driver circuit 31Da, not only the bit value TP1 to be output from the test output terminal TP_OUT. For example, the source driver circuit 31Da can input, to the encoding circuit 32D-1, a bit value ST1 indicating results of self-diagnosis of the source driver circuit 31Da. Moreover, the source driver circuit 31Da can input, to the encoding circuit 32D-1, a bit value RDY1 indicating that the source driver circuit 31Da is in the operational state. Furthermore, the other source driver circuits 31Db, 31Dc can input, to the encoding circuit 32D-1, a different signal showing the state of the source driver circuit 31Da in the same manner as the source driver circuit 31Da in FIG. 22. An encoded data value can be generated by the encoding circuit 32D-1 based on these signals to generate an encoded data value to accurately determine whether the internal circuit of the source driver board 3D-1 operates normally.

### Fourth Embodiment

In the examples according to the first to third embodiments, all of signal lines to transmit 8-bit data values DATA1[7:0], DATA2[7:0] of the data signals DATA1, DATA2 are used to transmit a test data value. However, at least a part of a plurality of signal lines used to transmit data signals between a control board and a source driver board can be used to transmit the test data value.

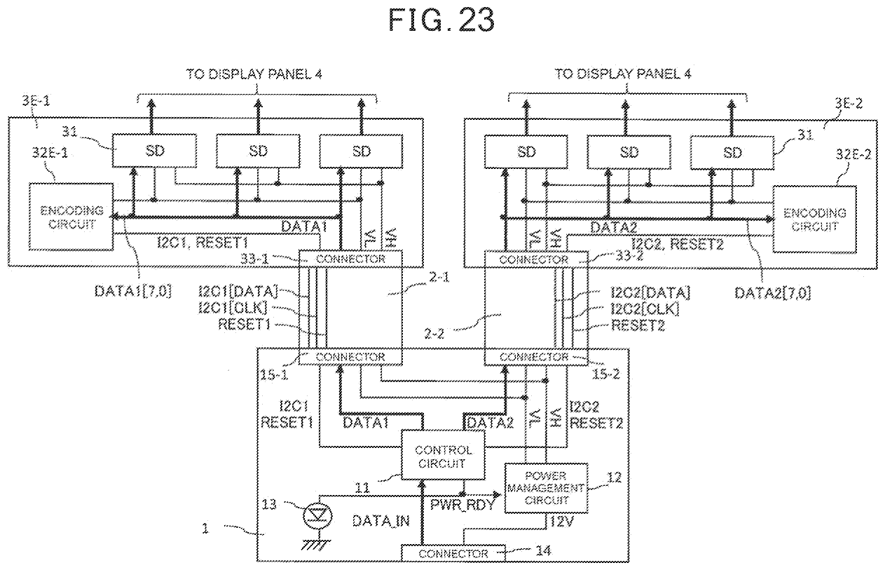

FIG. 23 shows a block diagram of an exemplary configuration of a control board 1 and source driver boards 3E-1, 3E-2 according to a fourth embodiment.

The control board 1 in FIG. 23 is configured in the same manner as the control board in FIG. 2. Cables 2-1, 2-2 in FIG. 23 are configured in the same manner as the cables in FIG. 3.

The source driver board 3E-1 comprises an encoding circuit 32E-1 in replacement of the encoding circuit 32-1 in FIG. 2. Only a 2-bit data value DATA1[7,0] of the data value DATA1[7:0] of the data signal DATA1 is input as a test data value to the encoding circuit 32E-1. The encoding circuit 32E-1 generates one encoded data value based on a plurality of test data values received from the control board 1.

In the same manner as the source driver board 3E-1, the source driver board 3E-2 comprises an encoding circuit 32E-2 in replacement of the encoding circuit 32-2 in FIG. 2. Only a 2-bit data value DATA2[7,0] of the data value DATA2[7:0] of the data signal DATA2 is input as a test data value to the encoding circuit 32E-2. The encoding circuit 32E-2 generates one encoded data value based on a plurality of test data values received from the control board 1.

Only at least a part of a plurality of signal lines 22 used to transmit data signals between the control board I and the source driver boards 3E-1, 3E-2 can be used to transmit the test data value. In particular, to detect the state in which the cables 2-1, 2-2 are inserted obliquely relative to connectors 15-1, 15-2, 33-1, 33-2, the test data value can be transmitted via at least two signal lines. In the example in FIG. 23, a pair of signal lines 22 being most distant mutually of the plurality of signal lines 22 used to transmit the data value DATA1[7:0] of the data signal DATA1 shown in FIG. 3 is used.

The control board 1 and the source driver boards 3E-1, 3E-2 according to the fourth embodiment have the following advantages, for example, in addition to the advantages of the first to third embodiments.

According to the fourth embodiment, the number of bits of the test data value can be reduced relative to a case of the first embodiment to cause a shift register of the encoding circuits 32E-1, 32E-2 to be associated with a lower-order generator polynomial, for example, a CRC-4 generator polynomial X⁴+X+1. Therefore, the circuit size of the shift register can be reduced and the size and cost of components can be reduced.

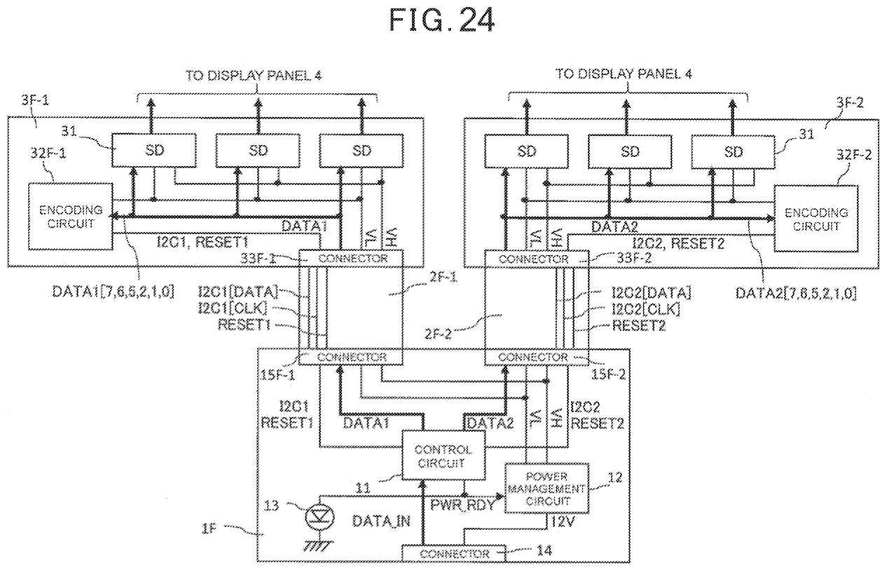

FIG. 24 shows a block diagram of an exemplary configuration of a control board 1F and source driver boards 3F-1, 3F-2 according to a variation of the fourth embodiment.

The control board 1F comprises connectors 15F-1, 15F-2 in replacement of the connectors 15-1, 15-2 in FIG. 2. As described later, while the number of electrodes E1 of the connectors 15F-1, 15F-2 is the same as that of the connector 15-1 in FIG. 3, arrangement of the electrodes E1 thereof differ from that of the connector 15-1.

The source driver board 3F-1 comprises an encoding circuit 32F-1 and a connector 33F-1 in replacement of the encoding circuit 32-1 and the connector 33-1 in FIG. 2. In the same manner as the connector 1.5F-1 of the control board. 1F, the connector 33F-1 comprises electrodes E3 in an arrangement being different from that for the connector 33-1 in FIG. 2. Only a 6-bit data value DATA1 [7,6,5,2,1,0] of the data value DATA1[7:0] of the data signal DATA1 is input as a test data value to the encoding circuit 32F-1. The encoding circuit 32F-1 generates one encoded data value based on a plurality of test data values received from the control board 1F.

The source driver board 3F-2 comprises an encoding circuit 32F-2 and a connector 33F-2 in replacement of the encoding circuit 32-2 and the connector 33-2 in FIG. 2. In the same manner as the connector 15F-2 of the control board 1F, the connector 33F-2 comprises electrodes E3 in an arrangement being different from that for the connector 33-2 in FIG. 2. Only a 6-bit data value DATA2[7,6,5,2,1,0] of the data value DATA2[7:0] of the data signal DATA2 is input as a test data value to the encoding circuit 32F-2. The encoding circuit 32F-2 generates one encoded. data value based on a plurality of test data values received from the control board 1F.

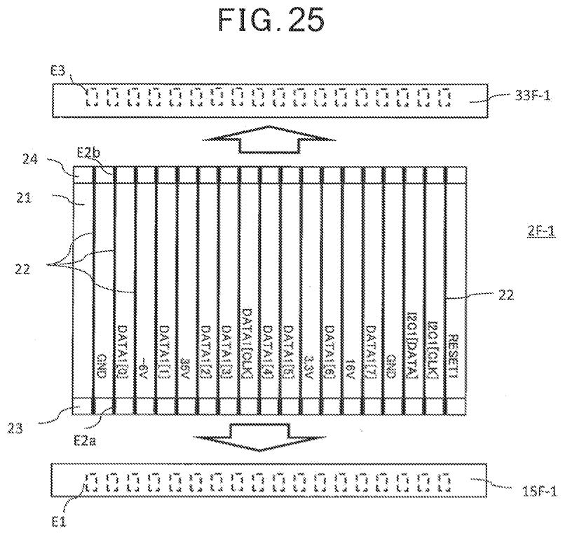

FIG. 25 is a block diagram showing an exemplary configuration of the cable 2F-1 in FIG. 24. The cable 2F-1 itself in FIG. 24 is the same as the cable 2-1 in FIG. 3. Arrangement of the electrodes E1, E3 of the connectors 15F-1, 33F-1 differs from that for the connectors 15-1, 33-1 in FIG. 3, so that each data signal and each power supply voltage are transmitted as shown in FIG. 25. Here, as described previously, only a data value DATA1[7,6,5,2,1,0] of the data signal DATA1 is used as a test data value. As shown in FIG. 24, the signal lines 22 to transmit the test data value are arranged such that they are adjacent to each side of signal lines 22 to which power supply voltages of −6V, 3.3V, 1.6V, and 35V are respectively applied.

Moreover, the cable 2F-2 is also configured in the same manner as the cable 2F-1 in FIG. 25.

According to a variation in FIGS. 24 and 25, as shown in FIG. 25, the electrodes E1, E3 of connectors 15F-1, 15F-2, 33F-1, 33F-2 can be arranged to surely detect the state (or the reverse state thereof) in which the signal lines 22 to which power supply voltages are applied are connected to electrodes to receive respective bits of the data signals DATA1, DATA2, not being connected to correct electrodes for power supply voltage.

Moreover, the variation in FIGS. 24 and 25 makes it possible to detect the state in which the cables 2F-1, 2F-2 are obliquely inserted to the connectors 15F-1, 15F-2, 33F-1, 33F-2 more surely than the case in FIG. 23.

### Fifth Embodiment

According to the first to fourth embodiments, in a case that a display apparatus comprises a plurality of source driver boards and the respective source driver boards comprises encoding circuits, respectively, the size and cost of components increase in accordance with the number of encoding circuits. Moreover, the control circuit of the control board needs to receive respective encoded data values or bit values from a plurality of encoding circuits, causing the processing time to also increase in accordance with the number of encoding circuits. Furthermore, in a case of the first embodiment, the control circuit needs to comprise a register to store therein encoded data values and reference values in correspondence with the respective encoding circuits, causing the circuit size to increase in accordance with the number of encoding circuits and the size and cost of components to increase. As the number of source driver boards increases, these problems become remarkable.

According to a fifth embodiment, a configuration in which, in a case that a plurality of source driver boards exist, the circuit size thereof can be reduced is explained.

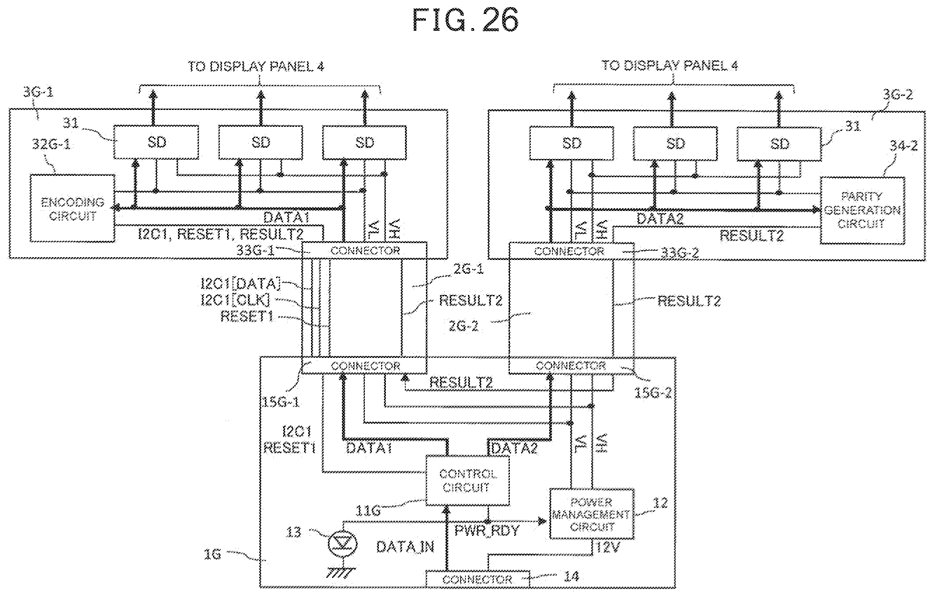

FIG. 26 shows a block diagram of an exemplary configuration of a control board 1G and source driver boards 3G-1 and 3G-2 according to a fifth embodiment.

The control board 1G comprises a control circuit 11G and connectors 15G-1, 15G-2 in replacement of the control circuit 11 and the connector 15-1, 15-2 in FIG. 2.

As described later, cables 2G-1, 2G-2 comprise a number of signal lines 22, the number being different from that of the cable 2-1 in FIG. 3, so that the connectors 15G-1, 15G-2 comprise a number of electrodes E1, the number being different from the connectors 15-1, 15-2 in FIG. 2.

In the same manner as the control circuit 11 in FIG. 2, test data values are transmitted to the source driver boards 3G-1, 3G-2, respectively, via at least a part of signal lines to transmit data signals DATA1, DATA2.

The source driver board 3G-2 comprises a parity generation circuit 34-2 and a connector 33G-2 in replacement of the encoding circuit 32-2 and the connector 33-2 in FIG. 2. In the same manner as the connector 15G-2 of the control board 1G, the connector 333-2 has a number of electrodes E3, the number being different from that for the connector 33-2 in FIG, 2, The parity generation circuit 34-2 generates a parity bit RESULTS2 based on a test data value transmitted to the source driver board 33-2 from the control board 1G.

While the control circuit 11G transmits/receives the I2C signal I2C1 and the reset signal RESET1 In the same manner as in FIG. 2, it does not transmit/receive the I2C signal I2C2 and the reset signal RESET2. In replacement of receiving the encoded data value M_DATA2 from the source driver board 33-2, the control board 1G receives the parity bit RESULTS2 being generated. based on a test data value and transmits the parity bit RESULTS2 as it is to the source driver board 33-1.

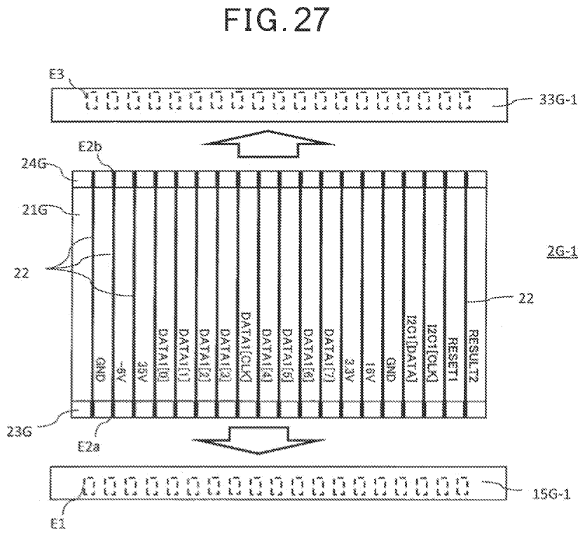

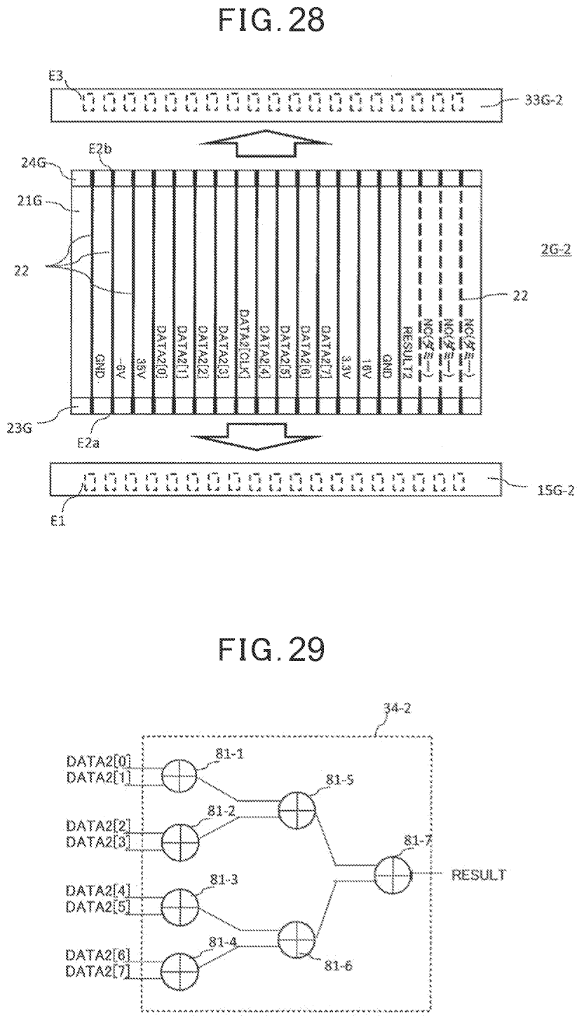

FIG. 27 shows an exemplary configuration of the cable 2G-1 in FIG. 26. FIG. 28 shows an exemplary configuration of the cable 2G-2 in FIG. 26. Each of the cables 2G-1, 2G-2 comprises a flexible board 213, a plurality of signal lines 22, and plugs 23G, 243. Each of the cables 23-1, 23-2 comprises a number of signal lines 22, the number being different from that for the cable 2-1 in FIG. 3. Therefore, the plugs 23G, 24G comprise a number of electrodes E2a, E2b, the number being different from that for the plugs 23, 24 in FIG. 3 and the flexible board 213 and the plugs 23G, 24G have sizes between different from those for the flexible board 21 and the plugs 23, 24 in FIG. 3.

In the example in FIG. 27, the plurality of signal lines 22 comprise one signal line to transmit the parity bit RESULTS2 to the source driver board 3G-1 from the control board 1G in addition to each signal line in FIG. 3. Therefore, in the example in FIG. 27, the cable 2G-1 comprises a total of 19 signal lines 22.

In the example in FIG. 28, the plurality of signal lines 22 comprises one signal line to transmit the parity bit RESULTS2 to the control board 1G from the source driver board 3G-2 in replacement of three signal lines to transmit the I2C signal 1202 and the reset signal RESET2 in the cable 2-2. Moreover, in the example in FIG. 28, the plurality of signal lines 22 comprise three dummy signal lines to match the number of signal lines in the cables 2G-1, 2G-2. Therefore, in the example in FIG. 28, the cable 2G-1 comprises a total of 19 signal lines 22.

The source driver board 3G-1 comprises an encoding circuit 32G-1 and a connector 33G-4 in replacement of the encoding circuit 32-1 and the connector 33-1 in FIG. 2. In the same manner as the connector 15G-1 of the control board 1G, the connector 33G-1 has a number of electrodes E3, the number being different from that for the connector 33-1 in FIG. 2. The encoding circuit 32G-1 generates one encoded data value based on a plurality of test values and the parity bit RESULTS2 received from the control board 1G.

Based on the encoded data value received only from the encoding circuit 32G-1, the control circuit 11G determines whether the cable 2G-1 is correctly connected to the connectors 15G-1, 33G-1 and the cable 2G-2 is correctly connected to the connectors 15G-2, 33G-2. The control circuit 11G outputs a control signal PWR_RDY indicating results of the determining.

FIG. 29 shows a block diagram of an exemplary configuration of the parity generation circuit 34-2 in FIG. 26. The parity generation circuit 34-2 comprises adders 81-1 to 81-7 and generates the parity bit RESULTS2 by mutually adding the data value DATA2[7:0] of the data signal DATA2, According to the parity generation circuit 34-2 in FIG. 29, comprising only adders makes it possible to reduce the circuit size more than the encoding circuit comprising the shift register and the M register.

According to the fifth embodiment, only one source driver board 3G-1 comprising the encoding circuit 32G-1 and the other source driver board 3G-2 comprising the parity generation circuit 34-2 in replacement of an encoding circuit make it possible to reduce the circuit size thereof and the size and cost of components.

Moreover, according to the fifth embodiment, the control circuit 11G needs to receive the encoded data value only from one encoding circuit 32G-1, making it possible to suppress an increase in processing time even in a case that the number of source driver boards increases.

Furthermore, according to the fifth embodiment, the control circuit 11G merely needs to comprise a register to store therein one encoded data value and one reference value, making it possible, even in a case that the number of source drive boards increases, to suppress an increase in the circuit size and suppress an increase in the size and cost of components.

Moreover, according to the fifth embodiment, signal lines required other than a signal line to supply a data signal and power to the source driver circuit 31 are only four signal lines to transmit a data value and a clock signal of an I2C signal, a reset signal, and the parity bit RESULTS2. Furthermore, in the cable 2G-2, a signal line required other than a signal line to supply a data signal and power to the source driver circuit 31 is only one signal line to transmit the parity bit RESULTS2. The fifth embodiment can be realized by addition of an extremely small number of signal lines.

As explained later, the fifth embodiment can be applied even in a case that three or more source driver boards exist.

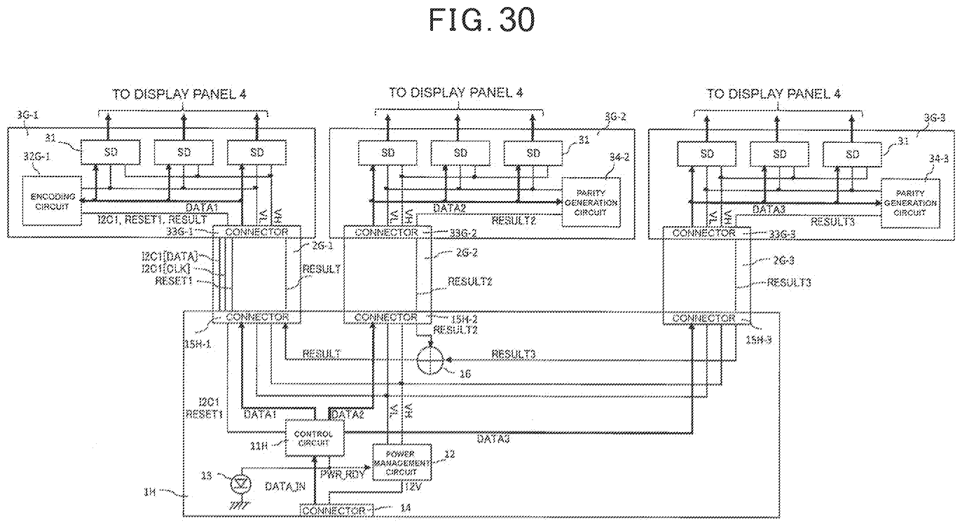

FIG. 30 shows a block diagram of an exemplary configuration of a control board 1H and source driver boards 3G-1 to 3G-3 according to a first variation of the fifth embodiment.

A cable 2G-3 is configured in the same manner as the cable 2G-2 in FIG. 28. Moreover, the source driver board 3G-3 is configured in the same manner as the source driver board 3G-2.

The control board 1H comprises a control circuit 11H and connectors 15H-1 to 15H-3 in replacement of the control circuit 11G, the connectors 15H-1 to 15H-3, and the parity generation circuit 16.

The connector 15H-1 is configured in the same manner as the connector 15G-1 in FIGS. 26 and 27. The connectors 15H-2 to 15H-3 are configured in the same manner as the connector 15G-2 in FIGS. 26 and 28.

In addition to data signals DATA1, DATA2, the control circuit 11H outputs a data signal DATA3 for the source driver board 3G-3. The control circuit 11H transmits a test data value to the source driver board 3G-3 via at least a part of signal lines to transmit the data signal DATA3 in addition to transmitting a test data value to the source driver boards 3G-1, 3G-2, respectively. The control circuit 11H receives a parity bit RESULTS3 being generated based on the test data value. The parity generation circuit 16 generates a parity bit RESULT based on parity bits RESULTS2, RESULTS3 received from the source driver boards 3G-2, 3G-3, respectively. The parity bit RESULT is transmitted to the source driver board 3G-1.

According to the control board 1H and the source driver board 3G-1 to 3G-3 in FIG. 30, even in a case that the three source driver boards 3G-1 to 3G-3 exist, advantages being the same as those in a case of FIG. 26 are obtained.

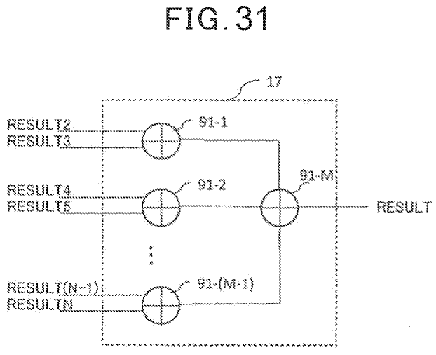

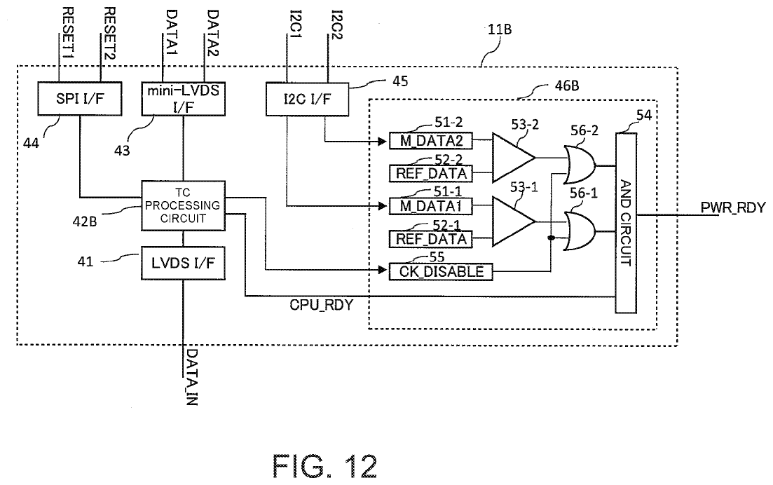

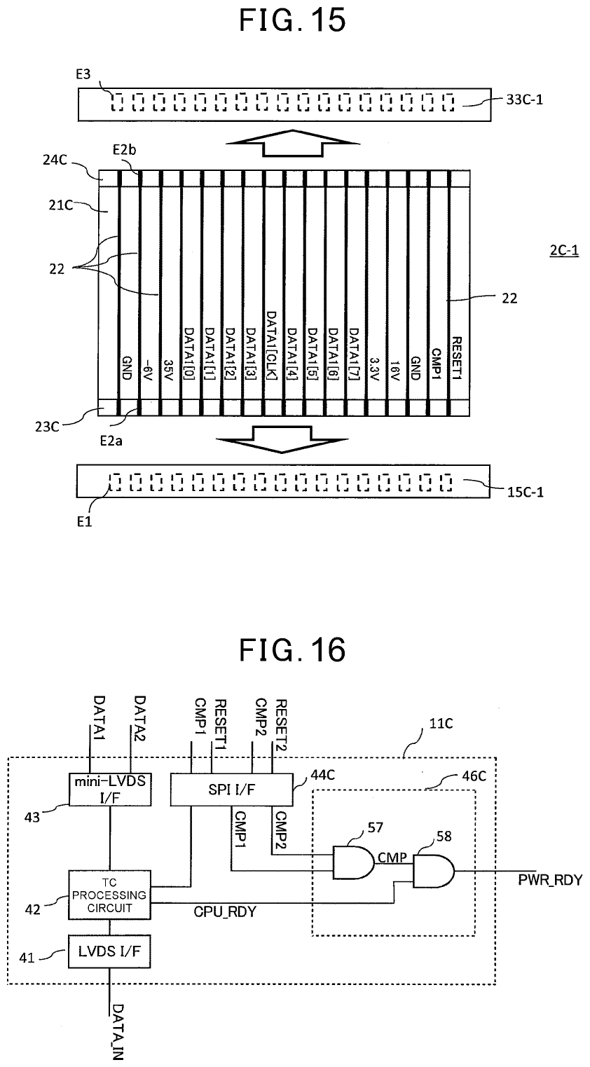

FIG. 31 shows a block diagram of an exemplary configuration of a parity generation circuit 17 of the control board according to a second variation of the fifth embodiment. In a case that four or more N source driver boards exist, the control board

comprises the parity generation circuit 17 in FIG. 31 in replacement of the parity generation circuit 16 in. FIG. 30. The parity generation circuit 17 generates the parity bit RESULT by mutually adding N−1 parity bits RESULT2, . . . , RESULTN being respectively received from a source driver board not comprising an encoding circuit. According to the parity generation circuit 17 in FIG. 31, even in a case that four or more source driver boards exist, advantages being the same as those in a case of FIGS. 26 and 30 are obtained.

While a case of a control circuit receiving an encoded data value from an encoding circuit (the first embodiment) is referred to in the fifth embodiment being explained in the above, the fifth embodiment can also be applied to a case in which the control circuit receives a bit value from an encoding circuit (the second embodiment).

### Other Embodiments

In the examples in FIGS. 12 and 16, the control circuit is configured so as to determine that all cables and connectors are correctly connected or they are not correctly connected in at least one location. In replacement thereof, the control circuit can be configured to determine whether the cable is correctly connected to the control circuit and the source driver board individually for each cable. The control circuit can report results of the determining to a user using a separate output apparatus (a light emitting diode), making it possible for the user to reconnect a cable not being correctly connected.

Two electronic apparatuses being mutually connected via a cable are riot limited to a control board and a source driver board of a display apparatus, so that they can be arbitrary apparatuses. Each of the embodiments can be applied to a system in which data is transmitted to an electronic apparatus comprising a power management circuit from an electronic apparatus not comprising a power management circuit, or can be applied to a system to transmit data in both directions between the two electronic apparatuses, for example.

While a case is explained in which a connector of each electronic apparatus is a socket and plugs are provided at opposite ends of a cable, a different arrangement of the socket and plugs can be used. For example, a cable can be provided with a socket and each electronic apparatus can be provided with plugs. Moreover, one end of the cable can be fixed to an electronic apparatus.

The control circuit can control transmission of an arbitrary signal, not being limited to power transmission.

Each embodiment and each variation being explained in the above can be combined with one another.

The invention is applicable to an arbitrary system comprising two electronic apparatuses being mutually connected via a cable comprising a plurality of signal lines.

1,1C,1G,1H Control board

2-1,2-2,2C-1,2C-2,2G-1˜2G-3 Cable

3-1,3-2,3C-1,3C-2,3D-1,3E-1,3E-2,3F-2,3F-2,3G-1˜3G-3 Source driver board

4 Display panel

11,11B,11C,11G,11H Control circuit

12 Power management circuit

13 Light emitting diode

14,15-1,15-2,15C-1,15C-2,15F-1,15F-2,15G-1,15G-2,15H-1˜15H-3 Connector

16,17 Parity generation circuit

21,21C,21G Flexible board

22 Signal line

23,24,23C,24C,23G,24G Plug

31,31Da-1-31Da-3 Source driver circuit

32-1,32-2,32C-1,32C-2,32D-1,32E-1,32E-2,32F-1,32F-2,32 G-1 Encoding circuit

33-1,33-2,33C-1,33C-2,33F-1,33F-2,33G-1-33G-3 Connector

34-2,34-3 Parity generation circuit

41 LVDS I/F (LVDS interface circuit)

42,42B TC (timing control) processing circuit

43 mini-LVDS I/F (mini-LVDS interface circuit)

44,44C SPI I/F (serial peripheral interface circuit)

45 I2C I/F (I2C interface circuit)

46,46B,46C Connection determination circuit

51-1-52-2 Register

53-1,53-2 Comparator

54 AND circuit (AND logic operation circuit)

55 Register

56-1,56-2 OR circuit (OR logic operation circuit)

57,58 AND circuit (AND logic operation circuit)

61,61D Shift register

62 M register

63 Register

64 Comparator

71-0 to 71-7 Adder

72-1,72-2 XOR circuit (XOR logic operation circuit)

73-1,73-2 Adder

FF0˜FF6 Flip flop

81-1˜81-7 Adder

91-1˜91-M Adder

1. An electronic apparatus being a first apparatus of a connection system comprising the first apparatus and a second apparatus, the first apparatus and the second apparatus being mutually connectable via a cable comprising a plurality of signal lines, the electronic apparatus comprising:
a first connector being connectable to the second apparatus via the cable; and
a control circuit,
wherein the control circuit
transmits a predetermined plurality of test data values to the second apparatus via first signal lines of the plurality of signal lines;
based on one encoded data value being generated from the plurality of test data values by the second apparatus, determines whether the plurality of test data values are correctly transmitted to the second apparatus; and
outputs a signal indicating whether the plurality of test data values are correctly transmitted to the second apparatus.

2. The electronic apparatus according to claim 1, wherein the control circuit
receives the encoded data value from the second apparatus via second signal lines of the plurality of signal lines; and,
in a case that the encoded data value being received from the second apparatus matches a reference value being precalculated based on the plurality of test data values, determines the plurality of test data values are correctly transmitted to the second apparatus.

3. The electronic apparatus according to claim 1, wherein the control circuit
receives a bit value indicating whether the encoded data value matches a reference value being precalculated based on the plurality of test data values from the second apparatus via second signal lines of the plurality of signal lines; and
determines whether the plurality of test data values are correctly transmitted to the second apparatus based on the bit value received from the second apparatus.

4. The electronic apparatus according to claim 1, further comprising a power management circuit to supply power to the second apparatus via third signal lines of the plurality of signal lines, wherein,
in a case that the plurality of test data values are correctly transmitted to the second apparatus, the control circuit controls the power management circuit so as to start supplying of power to the second apparatus.

5. The electronic apparatus according to claim 1, wherein
the first signal lines are at least a part of a plurality of signal lines to be used to transmit a data signal between the electronic apparatus and the second apparatus.

6. The electronic apparatus according to claim 1, wherein
the cable is a flat cable; and
the first signal lines are a pair of signal lines being most separated mutually of a plurality of signal lines to be used to transmit a data signal between the electronic apparatus and the second apparatus.

7. The electronic apparatus according to claim 4, wherein
the cable is a flat cable; and
the first signal lines are arranged such that, the respective first signal lines are adjacent to each side of the respective third signal lines.

8. The electronic apparatus according to claim 1, wherein
the control circuit transmits the plurality of test data values to the second apparatus via the first signal lines for each time the power of the electronic apparatus is turned on and determines whether the plurality of test data values are correctly transmitted to the second apparatus.

9. The electronic apparatus according to claim 1, wherein the control circuit
stores whether the plurality of test data values are correctly transmitted to the second apparatus; and,
in a case that power of the electronic apparatus is turned on and in a case that the plurality of test data values are never correctly transmitted to the second apparatus, transmits the plurality of test data values to the second apparatus via the first signal lines and determines whether the plurality of test data values are correctly transmitted to the second apparatus.

10. An electronic apparatus being a second apparatus of a connection system comprising a first apparatus and the second apparatus, the first apparatus and the second apparatus being mutually connectable via a cable comprising a plurality of signal lines, the electronic apparatus comprising:
a second connector being connectable to the first apparatus via the cable, the first apparatus being the electronic apparatus according to claim 1; and
an encoding circuit to generate the encoded data value based on the plurality of test data values being received from the first apparatus.

11. The electronic apparatus according to claim 10, wherein
the encoding circuit comprises a shift register being associated with a predetermined generator polynomial.

12. The electronic apparatus according to claim 10, wherein
the encoding circuit generates the encoded data value based on the plurality of test data values being received from the first apparatus and a bit value showing state of an internal circuit of the electronic apparatus.

13. A connection system, comprising a first apparatus and a second apparatus being mutually connectable via a cable comprising a plurality of signal lines,
wherein the first apparatus is an electronic apparatus comprising a first connector being connectable to the second apparatus via the cable and a control circuit, wherein the control circuit
transmits a predetermined plurality of test data values to the second apparatus via first signal lines of the plurality of signal lines;
based on one encoded data value being generated from the plurality of test data values by the second apparatus, determines whether the plurality of test data values are correctly transmitted to the second apparatus; and
outputs a signal indicating whether the plurality of test data values are correctly transmitted to the second apparatus, and
wherein the second apparatus is an electronic apparatus comprising a second connector being connectable to the first apparatus via the cable and an encoding circuit to generate the encoded data value based on the plurality of test data values being received from the first apparatus.

14. The connection system according to claim 13, wherein
the connection system comprises a third apparatus; and
the third apparatus comprises:
a third connector being connectable to the first apparatus via a cable comprising a plurality of signal lines; and
a first parity generation circuit to generate a first parity bit based on a test data value being transmitted from the first apparatus to the third apparatus, wherein
the first apparatus receives the first parity bit from the third apparatus and transmits the first parity bit to the second apparatus; and
the encoding circuit of the second apparatus generates the encoded data value based on the plurality of test data values and the first parity bit, the plurality of test data values and the first parity bit being received from the first apparatus.

15. The connection system according to claim 14, wherein
the connection system comprises a plurality of third apparatuses; and
the first apparatus comprises a second parity generation circuit to generate a second parity bit based on a plurality of first parity bits being received from the plurality of third apparatuses, respectively; and the first apparatus transmits the second parity bit in replacement of the first parity bit to the second apparatus.

16. The display apparatus comprising the connection system according to claim 13, wherein
the first apparatus is a control board comprising a timing controller; and
the second apparatus is a source driver board comprising a source driver circuit for a display panel.
